(19) United States
(12) Patent Application Publication
(10) Pub. No.: US 2017/0332493 A1
(43) Pub. Date: Nov. 16, 2017

(54) MOUNTING SUBSTRATE MANUFACTURING APPARATUS AND METHOD OF MANUFACTURING MOUNTING SUBSTRATE

(71) Applicant: Sharp Kabushiki Kaisha, Sakai City, Osaka (JP)

(72) Inventors: KATSUHIRO YAMAGUCHI, Sakai City (JP); NOBUHIRO NAKATA, Sakai City (JP); TOMOKI TAKAHARA, Sakai City (JP); YUKINORI MASUDA, Sakai City (JP)

(73) Assignee: Sharp Kabushiki Kaisha, Sakai City, Osaka (JP)

(21) Appl. No.: 15/531,390

(22) PCT Filed: Nov. 24, 2015
(86) PCT No.: PCT/JP2015/082831

§ 371 Date: May 26, 2017

(30) Foreign Application Priority Data
Dec. 1, 2014 (JP) 2014-243003

(51) Int. Cl. H05K 3/32; H05K 13/04

(52) U.S. Cl. CPC H05K 3/32; H05K 13/04; H05K 2203/163

(57) ABSTRACT

A driver mounting apparatus 40 includes a pressing device 50 that collectively presses drivers 21 to be mounted on terminals 23, 24 of bonded substrates 11ab, 11ab each of which is obtained by bonding a CF substrate 11a and an array substrate 11b having terminals 23, 24 with the terminals 23, 24 being uncovered, and substrate support members 41, 41 supporting the bonded substrates 11ab, 11ab, respectively. The pressing device 50 includes a driver-side pressing portion 51 and a substrate-side pressing portion 52. The substrate support members 41, 41 are movable independently from each other to position each of the bonded substrates 11ab, 11ab supported on the substrate support members 41, 41 with respect to the driver-side pressing portion 41.

### TECHNICAL FIELD

The present invention relates to a mounting substrate manufacturing apparatus and a method of manufacturing a mounting substrate.

### BACKGROUND ART

A Display device including a display panel such as a liquid crystal panel is used for portable electronic devices such as mobile phones, smartphones, and notebook computers. Such a display device includes a display panel including a display panel having a display portion displaying images, and semiconductor ships that drive the display panel by processing input signals from a signal supply source and generating output signals and supplying the output signals to the display portion. In such a display device that is classified as a small-to-medium size, the semiconductor chips may be preferably mounted by the chip-on-glass (COG) mounting method in that the semiconductor chips are directly mounted in an area of the display panel other than a display portion. An example of an apparatus of manufacturing such a display device is described in Patent Document 1.

The manufacturing apparatus of Patent Document 1 manufactures a liquid crystal cell including an upper substrate, a lower substrate that extends from the upper substrate by a certain width (a bonded substrate), and an IC circuit board mounted on an extended portion. In such a manufacturing apparatus, one liquid crystal cell where an IC circuit board is provisionally pressed is placed on a placing board (a substrate support member) and a pressing portion (mounting component-side pressing portion) is in contact with the IC circuit board for every liquid crystal cell and the IC circuit board is pressed on the liquid crystal cell.

### RELATED ART DOCUMENT

### Patent Document

Patent Document 1: Japanese Unexamined Patent Application Publication No. 2005-308943

### Problem to be Solved by the Invention

Such a manufacturing apparatus has been required to press collectively the mounting components such as the IC circuit board on terminals of the bonded substrate to improve manufacturing efficiency. In a configuration of collectively pressing the mounting components, it is required to cancel position errors of the bonded substrate (mounting components) and press precisely the mounting components with the mounting component-side pressing portion and achieve less occurrence of mounting failure of the mounting components.

A frame of the display device has been required to be smaller and the portion where the mounting components are mounted such as the extended portion is also reduced in width. As a result, the component such as the upper substrate may be arranged close to the mounting component. In such a case, other components may be in contact with the mounting component-side pressing portion if a pressing surface of the mounting component-side pressing portion is increased in size with respect to a pressed surface of each mounting component to press each mounting component surely.

### DISCLOSURE OF THE PRESENT INVENTION

The present invention was made in view of the above circumstances. An object is to achieve less occurrence of contact of the mounting component-side pressing portion and other components and less occurrence of mounting failure of mounting components when collectively mounting the mounting components on bonded substrates.

### Means for Solving the Problem

A mounting substrate manufacturing apparatus according to the present invention includes a pressing device that collectively presses mounting components that are to be mounted on terminals of bonded substrates each of which is obtained by bonding a first substrate and a second substrate having terminals with the terminals being uncovered, and substrate support members supporting the bonded substrates. The pressing device includes a mounting component-side pressing portion that is arranged close to the mounting components with respect to an arrangement direction in which the mounting components and the terminals are arranged, and a substrate-side pressing portion that is arranged close to the terminals with respect to the arrangement direction in which the mounting components and the terminals are arranged, the second substrate being between the substrate-side pressing portion and the terminals. The substrate support members are movable independently from each other to position each of the bonded substrates supported on the substrate support members with respect to the mounting component-side pressing portion.

According to the mounting substrate manufacturing apparatus of the present invention, the substrate support members are movable independently from each other. Therefore, in collectively pressing the mounting components on the respective bonded substrates, the mounting component-side pressing portion is less likely to be in contact with other components, and mounting failure of the mounting components is less likely to occur.

Specifically, as a result of the enthusiastic studies, the applicant found the following effects. When the mounting component is pressed on the bonded substrate, the mounting component and a mounting component-side pressing portion are overlapped such that a pressing surface of the mounting component-side pressing portion is greater than the pressed surface of the mounting component by at least from 0 mm to 0.1 mm. According to such a configuration, the electrical connection between the mounting component and the terminals is reliable. The applicant proposed a mounting substrate manufacturing apparatus that can press the mounting components collectively on the bonded substrates, and the configuration thereof is as follows. The bonded substrates are arranged on one substrate support member and a size of a pressing surface of the mounting component-side pressing portion is effectively larger than a pressed surface of the mounting component such that position errors of the bonded substrates (the mounting components) on the substrate support member are cancelled and each mounting component is overlapped with the mounting component-side pressing portion. However, according to requirement of reducing a frame size of the display device, in such a device, the pressing surface of the mounting component-side pressing portion cannot be much larger than the pressed surface of the mounting component to obviate the contact between the mounting component-side pressing portion and other components. Therefore, a configuration of the manufacturing apparatus is required to be improved to cancel the position errors of the bonded substrates (the mounting components). In the mounting substrate manufacturing apparatus of the present invention, the position relation between the mounting component-side pressing portion and the mounting component is adjusted for each bonded substrate when collectively pressing the mounting components on the respective bonded substrates. Therefore, position errors of each bonded substrate (each mounting component) are cancelled. According to such a configuration, the size of the pressing surface of the mounting component-side pressing portion is not necessary to be much larger than the size of the pressed surface of the mounting component. Thus, the mounting component-side pressing portion is pressed to the mounting component with being surely overlapped with the mounting component.

Preferable embodiments of the mounting substrate manufacturing apparatus may include the following configurations.

(1) Each of the substrate support members may include XYθ moving means for moving the bonded substrate in a plate surface direction thereof and around an axis that is vertical to the plate surface direction. According to such a configuration, a position of the bonded substrate around an axis that is vertical to a plate surface of the bonded substrate is adjusted. Such adjustment of the position around the axis is difficult if one substrate support member supports multiple bonded substrates. Further, the mounting component-side pressing portion is pressed on the mounting component with being surely overlapped with the mounting component and not in contact with other components.

(2) Each of the substrate support members may include Z moving means for moving the bonded substrate in a direction vertical to the plate surface direction of the bonded substrate. According to such a configuration, each of the bonded substrates is positioned with respect to the pressing device in the direction vertical to the plate surface of the bonded substrate even if the bonded substrates and the mounting components have variation in thickness dimensions thereof. Therefore, a force is not applied to the mounting component to be rotated when the mounting component is pressed. The mounting component is pressed with surely overlapped with the mounting component-side pressing portion, even if the extended amount of the mounting component-side pressing portion from the mounting component is small.

(3) The mounting substrate manufacturing apparatus may further include position sensing means directly sensing the mounting component that is provisionally pressed on the terminals before being pressed by the pressing device and detecting a position of at least a first substrate side edge portion of the mounting component. Each of the bonded substrates may be positioned with respect to the mounting component-side pressing portion by the substrate support member based on information regarding the position of the mounting component sensed by the position sensing means. According to such a configuration, even if the mounting components have great size tolerances or the mount positions of the mounting components with respect to the bonded substrates are greatly varied, the position of each mounting component is directly sensed by the position sensing means. Therefore, accuracy of positioning the mounting component and the mounting component-side pressing portion is improved, compared to means of positioning the mounting component based on detected position of an alignment mark on each substrate.

(4) The position sensing means may be a camera that directly takes an image of the mounting component and senses the position of at least the first substrate-side edge portion of the mounting component. According to such a configuration, the camera directly takes an image of the mounting component and the image data is processed. Thus, the position of each mounting component is effectively obtained.

(5) A method of manufacturing a mounting substrate according to the present invention includes a provisional pressing process in which mounting components are provisionally pressed on terminals on bonded substrates each of which is obtained by bonding a first substrate and a second substrate having the terminals with uncovered, a positioning process in which the bonded substrates having the mounting components provisionally pressed are supported on substrate support members each of which is movable independently, and each of the substrate support members is moved and positioned with respect to a mounting component-side pressing portion that is included in a pressing device and arranged close to the mounting components with respect to an arrangement direction in which the mounting components and the terminals are arranged, and a pressing process in which the mounting component-side pressing portion and a substrate-side pressing portion of the pressing device are relatively closer to each other, the substrate-side pressing portion being arranged close to the terminals having the second substrate therebetween with respect to the arrangement direction in which the mounting components and the terminals are arranged, and the mounting components are collectively pressed on the terminals on the respective bonded substrates.

The method of mounting a driver according to the present embodiment includes the positioning process in which each of the bonded substrates is positioned with respect to the mounting component-side pressing portion. Therefore, in collectively pressing the mounting components on the respective bonded substrates, the mounting component-side pressing portion is less likely to be in contact with other components, and mounting failure of the mounting components is less likely to occur.

Specifically, as a result of the enthusiastic studies, the applicant found the following effects. When the mounting component is pressed on the bonded substrate, the mounting component and a mounting component-side pressing portion are overlapped such that a pressing surface of the mounting component-side pressing portion is greater than the pressed surface of the mounting component by at least from 0 mm to 0.1 mm. According to such a configuration, the electrical connection between the mounting component and the terminals is reliable. The applicant proposed a method of manufacturing a mounting substrate in which the mounting components are collectively pressed on the bonded substrates as follows. The bonded substrates are arranged on one substrate support member and a size of a pressing surface of the mounting component-side pressing portion is effectively larger than a pressed surface of the mounting component such that position errors of the bonded substrates (the mounting components) on the substrate support member are cancelled and each mounting component is overlapped with the mounting component-side pressing portion. However, according to requirement of reducing a frame size of the display device, in the above method, the pressing surface of the mounting component-side pressing portion cannot be much larger than the pressed surface of the mounting component to obviate the contact between the mounting component-side pressing portion and other components. Therefore, a configuration of the manufacturing apparatus is required to be improved to cancel the position errors of the bonded substrates (the mounting components). In the method of manufacturing a mounting substrate of the present invention, the position relation between the mounting component-side pressing portion and the mounting component is adjusted for each bonded substrate when collectively pressing the mounting components on the respective bonded substrates. Therefore, position errors of each bonded substrate (each mounting component) are cancelled. Accordingly, the size of the pressing surface of the mounting component-side pressing portion is not necessary to be much larger than the size of the pressed surface of the mounting component. Thus, the mounting component-side pressing portion is pressed to the mounting component with being surely overlapped with the mounting component.

Preferable embodiments of the method of manufacturing mounting substrate may include the following configurations.

(1) In the positioning process, the mounting components that are provisionally pressed may be directly sensed by position sensing means to detect a position of at least a first substrate-side edge portion of each mounting component. According to such a configuration, each of the bonded substrates may be positioned with respect to the pressing device by moving the substrate support member based on information regarding the position of the mounting component sensed by the position sensing means. Even if the mounting components have great size tolerances or the mount positions of the mounting components with respect to the bonded substrates are greatly varied, accuracy of positioning the mounting component and the mounting component-side pressing portion is improved, compared to means of positioning the mounting component based on detected position of an alignment mark on each substrate.

### Advantageous Effect of the Invention

According to the present invention, the mounting component-side pressing portion is less likely to be in contact with other components and mounting failure of the mounting components is less likely to occur in collectively mounting the mounting components on bonded substrates.

### BRIEF DESCRIPTION OF THE DRAWINGS

FIG. 1 is a schematic plan view illustrating a connection configuration of a liquid crystal panel where a driver is mounted, a flexible printed circuit board, and a control circuit board according to a first embodiment of the present invention.

FIG. 2 is a schematic cross-sectional view of a liquid crystal display device illustrating a cross-sectional configuration along a long-side direction thereof.

FIG. 3 is a schematic cross-sectional view illustrating a cross-sectional configuration of the liquid crystal panel.

FIG. 4 is a schematic plan view illustrating a mounting area of an array substrate of the liquid crystal panel where the driver and the flexible printed circuit board are mounted.

FIG. 5 is a cross-sectional view taken along line A-A in FIG. 4.

FIG. 6 is a cross-sectional view taken along line B-B in FIG. 4.

FIG. 7 is a plan view illustrating the driver mounting apparatus where substrate support members are in a retreat position.

FIG. 8 is a plan view illustrating the driver mounting apparatus where the substrate support members are in a forward position.

FIG. 9 is a cross-sectional view taken along line A-A in FIG. 4 and illustrating the driver mounting apparatus in a positioning process.

FIG. 10 is a cross-sectional view taken along line A-A in FIG. 4 and illustrating the driver mounting apparatus in a pressing process.

FIG. 11 is a cross-sectional view taken along line B-B in FIG. 4 and illustrating the driver mounting apparatus in the pressing process.

FIG. 12 is a schematic plan view illustrating a mounting area of an array substrate of the liquid crystal panel where the driver and the flexible printed circuit board are mounted according to a second embodiment of the present invention.

FIG. 13 is a cross-sectional view illustrating a flexible printed circuit board mounting apparatus in a positioning process.

FIG. 14 is a cross-sectional view illustrating the flexible printed circuit board mounting apparatus in a pressing process.

### MODE FOR CARRYING OUT THE INVENTION

### First Embodiment

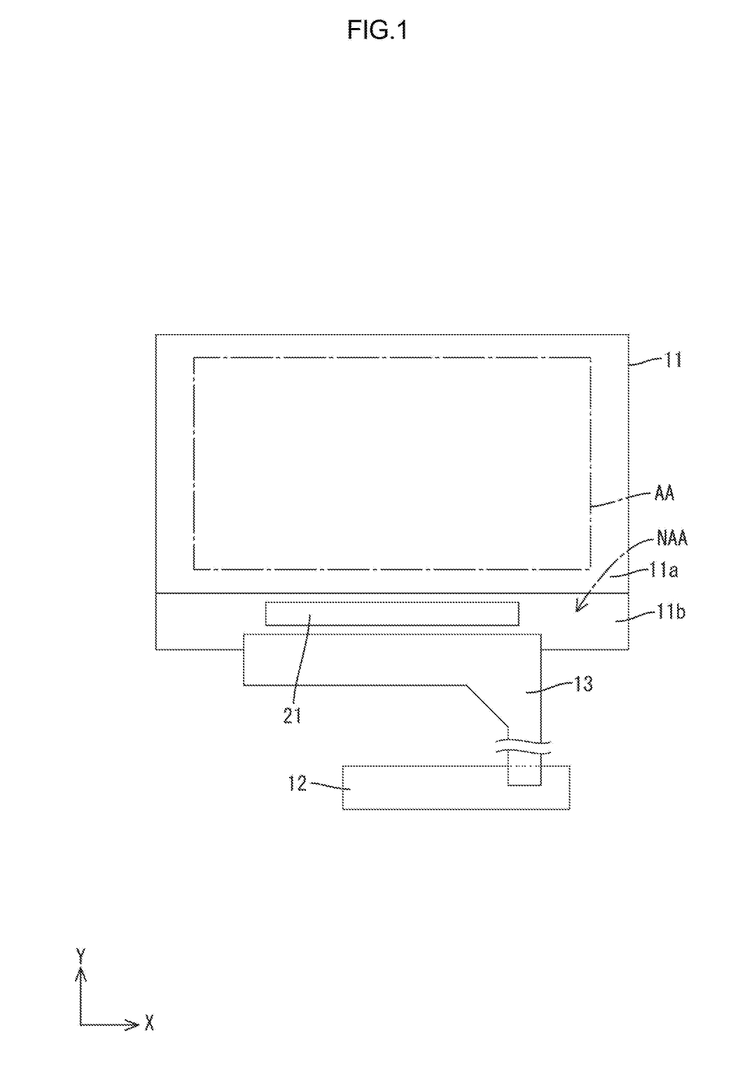

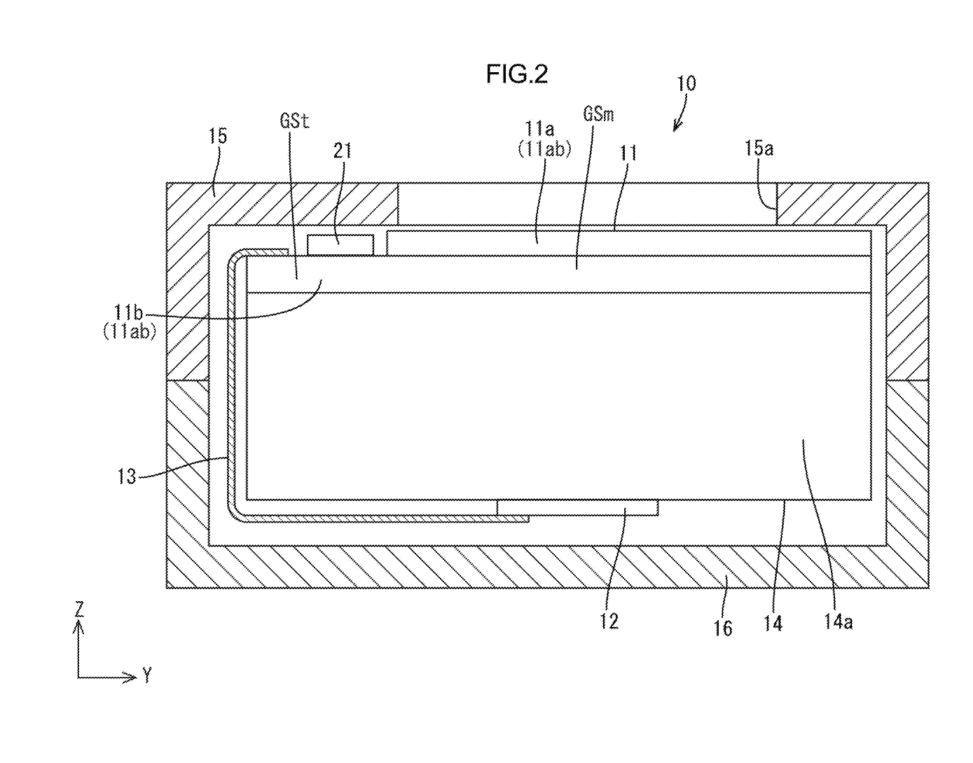

A first embodiment will be described with reference to FIGS. 1 to 11. In the present embodiment, a method of manufacturing a liquid crystal panel (mounting substrate) 11 included in a liquid crystal display device 10 and a driver mounting device (a manufacturing device) 40 used in the manufacturing method will be described. X-axis, Y-axis and Z-axis may be indicated in the drawings. The axes in each drawing correspond to the respective axes in other drawings. The vertical direction is defined based on FIG. 2. An upper side and a lower side in FIG. 2 correspond to a front side and a back side of the liquid crystal display device 10, respectively.

As illustrated in FIGS. 1 and 2, a liquid crystal display device 10 includes the liquid crystal panel 11, a control circuit board (an external signal source) 12, a flexible printed circuit board (an external connector) 13, and a backlight unit (a lighting device) 14. A driver (a mounting component) 21 is mounted on the liquid crystal panel 11. The control circuit board 12 supplies various input signals from outside to the driver 21. The flexible printed circuit board 13 electrically connects the liquid crystal panel 11 and the external control circuit board 12. The backlight unit 14 is an external light source that supplies light to the liquid crystal panel 11. The liquid crystal display device 10 further includes a pair of exterior components 15 and 16 that are front and rear components used in a pair to hold the liquid crystal panel 11 and the backlight unit 14 that are attached together. The exterior component 15 on the front has an opening 15a through which images displayed on the liquid crystal panel 11 are viewed from the outside. The liquid crystal display device 10 according to this embodiment may be used in various kinds of electronic devices (not illustrated) such as handheld terminals (including electronic books and PDAs), mobile phones (including smartphones), notebook computers (including tablet computers), digital photo frames, portable video game players, and electronic-ink papers. The liquid crystal panel 11 in the liquid crystal display device 10 is in a range between some inches to ten and some inches. Namely, the liquid crystal panel 11 is in a size that is classified as a small or a small-to-medium.

The backlight unit 14 will be described. As illustrated in FIG. 2, the backlight unit 14 includes a chassis 14a, light sources (e.g., cold cathode fluorescent tubes, LEDs, organic ELs), an optical member. The chassis 14a has a box-like shape with an opening on the front (on a liquid crystal panel 11 side). The light sources, which are not illustrated, are disposed inside the chassis 14a. The optical member, which is not illustrated, is arranged so as to cover the opening of the chassis 14a. The optical member has a function to convert light from the light sources into planar light.

Next, the liquid crystal panel 11 will be described. As illustrated in FIG. 1, the liquid crystal panel 11 has a horizontally-long rectangular overall shape. The liquid crystal panel 11 includes a display area (an active area) AA that is off centered toward one of ends of a short dimension thereof (the upper side in FIG. 1). The driver 21 and the flexible printed circuit board 13 are arranged at the other end of the short dimension of the liquid crystal panel 11 (the lower side in FIG. 1). An area of the liquid crystal panel 11 outside the display area AA is a non-display area (non-active area) NAA in which images are not displayed and the non-display area includes a mounting area in which the driver 21 and the flexible printed circuit board 13 are mounted. A short-side direction and a long-side direction of the liquid crystal panel 11 correspond to the X-axis direction and the Y-axis direction in each drawing. In FIG. 1, a chain line box slightly smaller than the CF board 11a indicates a boundary of the display area AA. An area outside the chain line is the non-display area NAA.

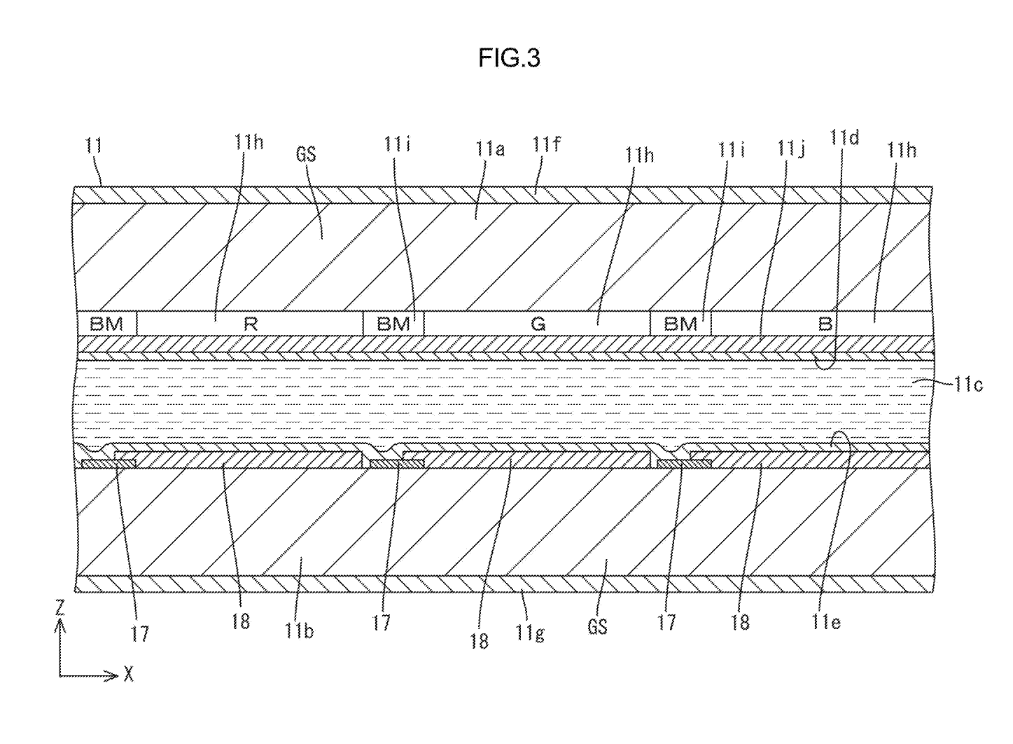

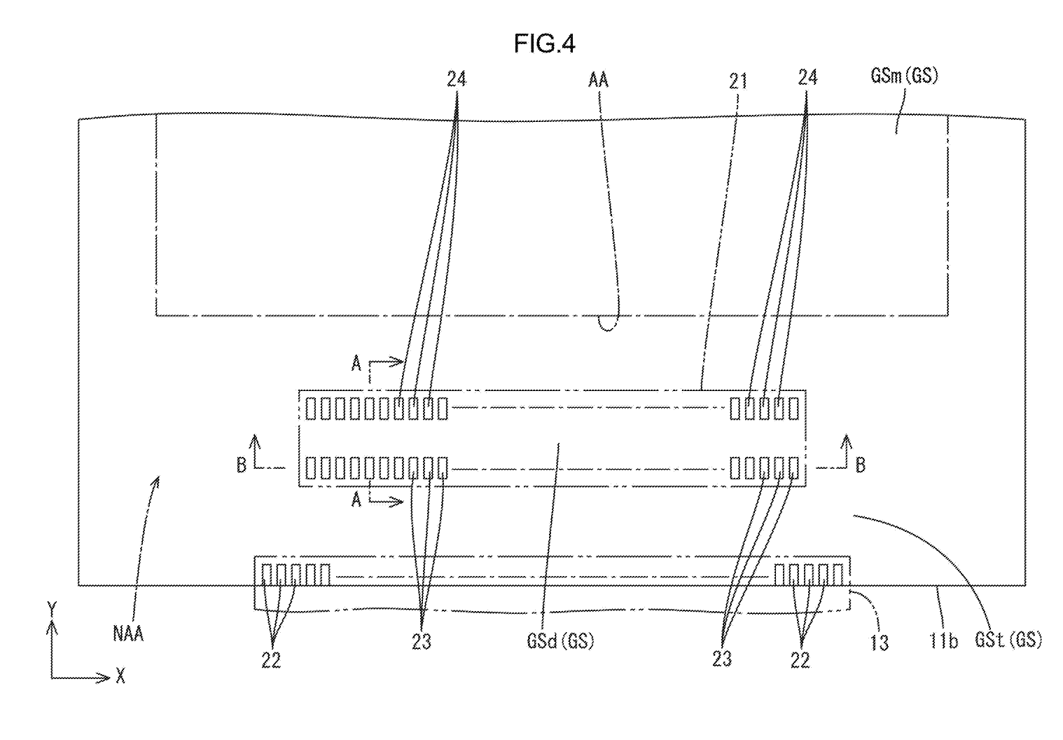

As illustrated in FIG. 3, the liquid crystal panel 11 includes a bonded substrate 11ab that is obtained by attaching a pair of transparent substrates (having high transmissivity) (a first substrate and a second substrate) 11a and 11b, and a liquid crystal layer 11c between the substrates 11a and 11b. The liquid crystal layer 11c includes liquid crystal molecules having optical characteristics that vary according to application of electric field. The substrates 11a and 11b are bonded together with a sealing agent, which is not illustrated, with a gap therebetween. The substrates 11a, 11b include glass substrates GS made of alkali-free glass or quartz glass, and includes films that are layered on the glass substrates GS with the known photolithography method. The bonded substrate 11ab includes a CF substrate (an opposing substrate, a first substrate) on the front (on a front surface side) and an array substrate (a component substrate, an active matrix substrate, a second substrate) 11b on a back side (on a rear surface side). As illustrated in FIGS. 1 and 2, the CF substrate 11a has a long-side dimension substantially same as that of the array substrate 11b and has a short-side dimension smaller than that of the array substrate 11b. The CF substrate 11a and the array substrate 11b are bonded together such that long-side edges (upper-side edges in FIG. 1) thereof are aligned with each other. According to such a configuration, the CF substrate 11a and the array substrate 11b are not overlapped with each other in the other long-side edge portions thereof (lower-side edges in FIG. 1) over a certain area and the long-side edge portion of the array substrate 11b is exposed outside on the front and rear plate surfaces thereof. Thus, the exposed portion is a mounting area where the driver 21 and the flexible printed circuit board 13 are mounted. Namely, the CF substrate 11a is bonded to the array substrate 11b such that the CF substrate 11a is opposite a plate surface of the array substrate 11b where the driver 21 and the flexible printed circuit board 13 are mounted and the terminal portions 22 to 24 that are to be connected to the driver 21 and the flexible printed circuit board 13 are exposed. The glass substrate GS of the array substrate 11b includes a substrate main portion GSm where the CF substrate 11a and a polarizing plate 11g are bonded and a terminal forming portion GSt that is not overlapped with the CF substrate 11a and the polarizing plate 11g and on which the terminals 22 to 24 are formed (see FIG. 4). Alignment films 11d and 11e are formed on inner surfaces of the substrates 11a and 11b, respectively, for aligning the liquid crystal molecules included in the liquid crystal layer 11c. Polarizing plates 11f and 11g are bonded to outer surfaces of the substrates 11a and 11b, respectively.

Next, components on the array substrate 11b and the CF substrate 11a in the display area AA will be described in detail. As illustrated in FIG. 3, a number of the TFTs (thin film transistors) 17 and a number of pixel electrodes 18 are arranged in a matrix on the inner surface of the array substrate 11b (the liquid crystal layer 11c side, the opposed surface side opposed to the CF substrate 11a). Furthermore, the gate lines and the source lines 20 (both not illustrated) are arranged in a grid to surround the TFTs 17 and the pixel electrodes 18. Namely, the TFTs 17 and the pixel electrodes 18 are arranged at the respective intersections of the gate lines and the source lines and in a grid. The gate lines and the source lines are connected to gate electrodes and source electrodes of the TFTs 17, respectively. The pixel electrodes 18 are connected to drain electrodes 17c of the TFTs 17. Each of the pixel electrodes 18 has a vertically long rectangular shape in a plan view. The pixel electrodes 18 are made of transparent electrode material such as indium tin oxide (ITO) and zinc oxide (ZnO). Furthermore, an auxiliary capacitor line (not illustrated) may be formed to be parallel to the gate lines and to cross the pixel electrodes 18.

As illustrated in FIG. 3, color filters 11h are formed on the CF substrate 11a. The color filters 11h include red (R), green (G), and blue (B) color portions are arranged in a matrix to overlap the pixel electrodes 18 on the array substrate 11b in a plan view. A light blocking layer 11i having a grid shape (a black matrix) is formed between the color portions included in the color filters 11h for reducing color mixture. The light blocking layer 11i is arranged to overlap the gate lines and the source lines in a plan view. A counter electrode 11j is formed in a solid pattern on surfaces of the color filters 11h and the light blocking layer 11i. The counter electrode 11j is opposed to the pixel electrodes 18 on the array substrate 11b. In the liquid crystal panel 11, as illustrated in FIGS. 1 to 3, the R (red) color portion, the G (green) color portion, the B (blue) color portion, and three pixel electrodes 18 opposed to the color portions form a display pixel that is a display unit. Each display pixel includes a red pixel including the R color portion, a green pixel including the G color portion, and a blue pixel including the B color portion. The color pixels are repeatedly arranged along a row direction (the X-axis direction) on a plate surface of the liquid crystal panel to form lines of pixels. The lines of pixels are arranged along the column direction (the Y-axis direction).

The components connected to the liquid crystal panel 11 will be described. As illustrated in FIGS. 1 and 2, the control circuit board 12 is attached to the back surface of the chassis 14a of the backlight unit 14 (an outer surface on a side opposite from the liquid crystal panel 11 side) with a screw or other fixing member. The control circuit board 12 includes a substrate made of paper phenol or glass epoxy resin and electronic components mounted on the substrate for supplying various kinds of input signals to the driver 21. The control circuit board 12 further includes predetermined traces (conductive lines), which are not illustrated, routed on the substrate. One of ends (a first end) of the flexible printed circuit board 13 is electrically and mechanically connected to the control circuit board 12 via an anisotropic conductive film, which is not illustrated.

As illustrated in FIG. 2, the flexible printed circuit board 13 includes a base member made of synthetic resin (e.g., polyimide resin) having an insulating property and flexibility. The flexible printed circuit board 13 includes traces (not illustrated) on the base member. As described earlier, the first end, which is one of ends of the flexible printed circuit board 13 with respect to the length direction thereof, is connected to the control circuit board 12 on the back surface of the chassis 14a. The other end (a second end) of the flexible printed circuit board 13 is connected to the second end of the array substrate 11b of the liquid crystal panel 11. Namely, the flexible printed circuit board 13 is folded such that a shape in a cross-sectional view is a U-like shape. The ends of the flexible printed circuit board 13 with respect to the length direction include exposed portions of traces which form terminals (not illustrated). The terminals are electrically connected to the control circuit board 12 and the liquid crystal panel 11. According to the configuration, the input signals supplied by the control circuit board 12 are transmitted to the liquid crystal panel 11.

As illustrated in FIG. 1, the driver 21 includes an LSI chip including a driver circuit therein. The driver 21 operates according to signals supplied by the control circuit board 12, which is a signal source, process the input signals supplied by the control circuit board 12, which is a signal source, generates output signals, and sends the output signals to the display area AA of the liquid crystal panel 11. The LSI chip included in the driver 21 includes traces and components formed on a silicon wafer that contains silicon with high purity. The driver 21 has a horizontally long rectangular shape in the plan view. The driver 21 is orientated such that a long-side direction thereof is along the long-side direction of the liquid crystal panel 11. The driver 21 has an upper surface that is a pressed surface 21a that is pressed by a driver-side pressing portion 51, which will be described later. The driver 21 is directly mounted on the array substrate 11b in the non-display area NAA of the liquid crystal panel 11 with the COG (chip on glass) mounting technology. The drivers 21 have a size tolerance of approximately ±40 μm to ±100 μm due to a degree of accuracy of dicing during the manufacturing process thereof. A certain tolerance is set for a position on each liquid crystal panel 11 where the driver 21 is mounted. Thus, the liquid crystal panels 11 have certain tolerances for the shape and the position of the driver 21 that is to be mounted.

Next, a connection configuration of the flexible printed circuit board 13 and the driver 21 that are connected to the non-display area NAA of the array substrate 11b will be described. As illustrated in FIG. 1, edge portions of the respective driver 21 and the flexible printed circuit board 13 are mounted on a non-overlapping portion of the non-display area NAA of the array substrate 11b. The non-overlapping portion is not overlapped with the CF substrate 11a. An edge portion of the flexible printed circuit board 13 is arranged on an edge portion of the array substrate 11b along a short side thereof. That is, the driver 21 is arranged in the non-display area NAA and between the display area AA and the flexible printed circuit board 13. Another edge portion of the flexible printed circuit board 13 (to be mounted on the liquid crystal panel 11) is on an opposite side from the display area AA with respect to the driver 21 (on an edge portion of the array substrate 11b). The edge portion of the flexible printed circuit board 13 is mounted on a middle portion in a short-side edge portion of the array substrate 11b. The mounted edge portion of the flexible printed circuit board 13 extends along the short-side edge of the array substrate 11b (the short-side direction, the X-axis direction). A dimension of the edge portion of the flexible printed circuit board 13 mounted on the array substrate 11b is smaller than a long-side dimension of the array substrate 11b. The driver 21 is mounted in a middle portion of the non-display area NAA with respect to the short-side direction of the array substrate 11b such that the long-side direction of the driver 21 corresponds with the short-side direction of the array substrate 11b (the X-axis direction).

As illustrated in FIG. 4, external connection terminals 22 are formed in the mounting area of the array board 11b in which the flexible printed circuit board 13 is mounted. The external connection terminals 22 receive supply of input signals from the flexible printed circuit board 13. Panel-side input terminals (substrate-side input terminals) 23 and panel-side output terminals (substrate-side output terminals) 24 are mounted in the mounting area of the array substrate 11b in which the driver 21 is to be mounted. Input signals are supplied from the panel-side input terminals to the driver 21, and output signals from the driver 21 are supplied to the panel-side output terminals 24. Relay traces (not illustrated) are arranged in the non-display area NAA and between the flexible printed circuit board 13 mounting area and the driver 21 mounting area, and the external connection terminals 22 and the panel-side input terminals 23 are electrically connected to each other via the relay traces. The driver 21 includes driver-side input terminals (mounting component-side input terminals) 25 and driver-side output terminals (mounting component-side output terminals) 26. The driver-side input terminals 25 are electrically connected to the panel-side input terminals 23, and the driver-side output terminals 26 are electrically connected to the panel-side output terminals 24. In FIG. 4, the flexible printed circuit board 13 and the driver 21 are illustrated with two-dot chain lines. In FIG. 4, a dashed line indicates an outer boundary of the display area AA and the area outside the chain line is the non-display area NAA.

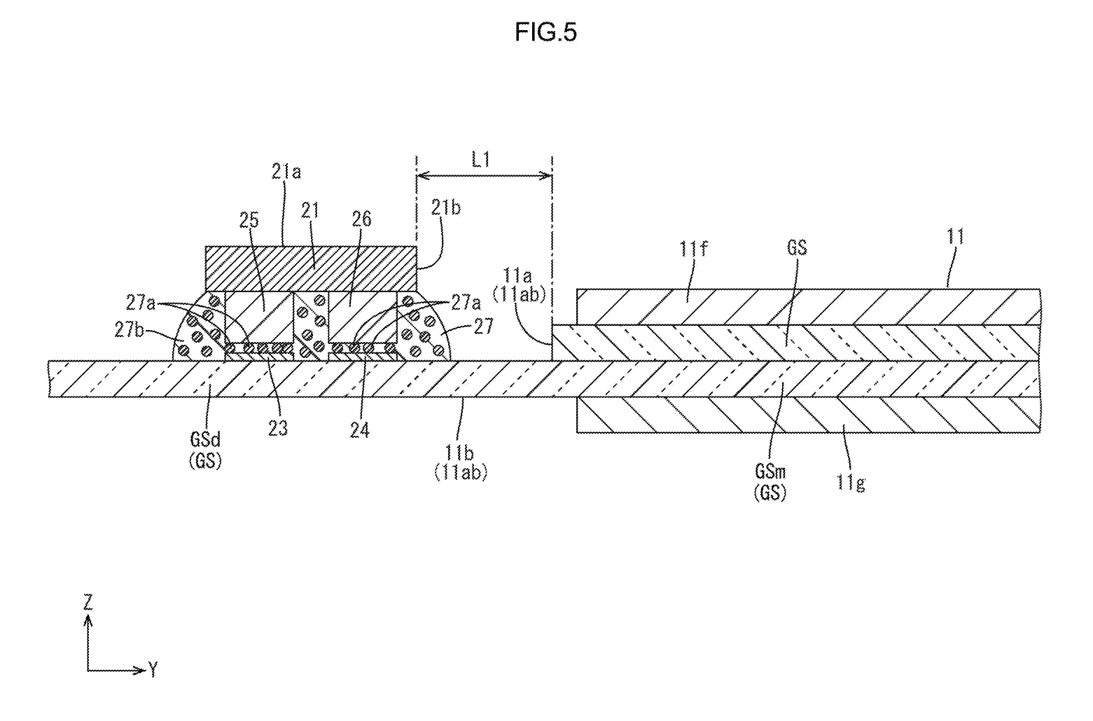

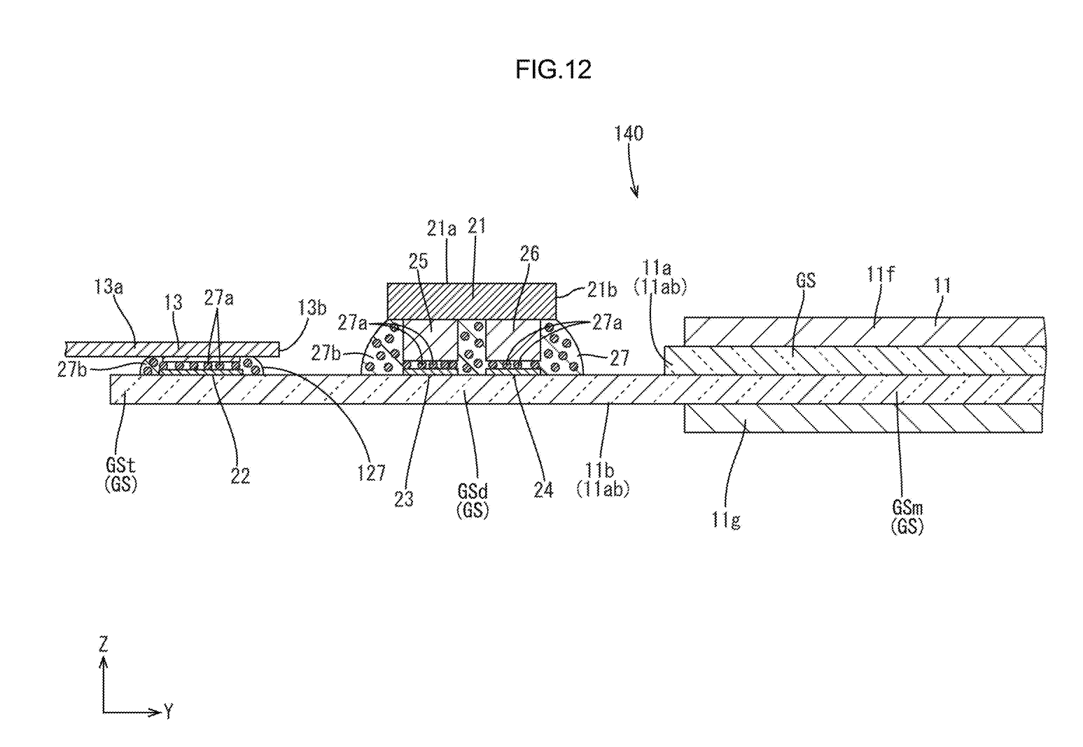

As illustrated in FIG. 5, each of the panel-side input terminals 23 (corresponding to terminals in claim) and the panel-side output terminals (corresponding to terminals in claim 24 is made of a metal thin film similar to that of the gate lines and the source lines, and surfaces of the metal thin film is covered with transparent electrode material such as ITO or ZnO same as the pixel electrode 18. Therefore, the panel-side input terminals 23 and the panel-side output terminals 24 are formed on the array substrate 11b with the known photolithography method at a same time when the gate lines or the source lines, and the pixel electrodes 18 are formed with patterning in a process of manufacturing the liquid crystal panel 11 (the array substrate 11b). An anisotropic conductive film (ACF, anisotropic conductive material) 27 is arranged on the panel-side input terminals 23 and the panel-side output terminals 24. The driver-side input terminals 25 of the driver 21 are electrically connected to the panel-side input terminals 23 and the driver-side output terminals 26 are electrically connected to the panel-side output terminals 24 via conductive particles 27a contained in the anisotropic conductive film 27. The anisotropic conductive film 27 includes the conductive particles 27a made of metal material and thermosetting resin 27b in which the conductive particles 27a are dispersed. The terminals 23-26 are connected to each other via the anisotropic conductive film 27 by mounting the driver 21 on the array substrate 11b using a driver mounting apparatus 40, which will be described in detail later. The external connection terminals 22 illustrated in FIG. 12 have a cross-sectional configuration similar to those of the panel-side input terminals 23 and the panel-side output terminals 24, and the external connection terminals 22 are electrically connected to the terminals of the flexible printed circuit board 13 via the anisotropic conductive film 127.

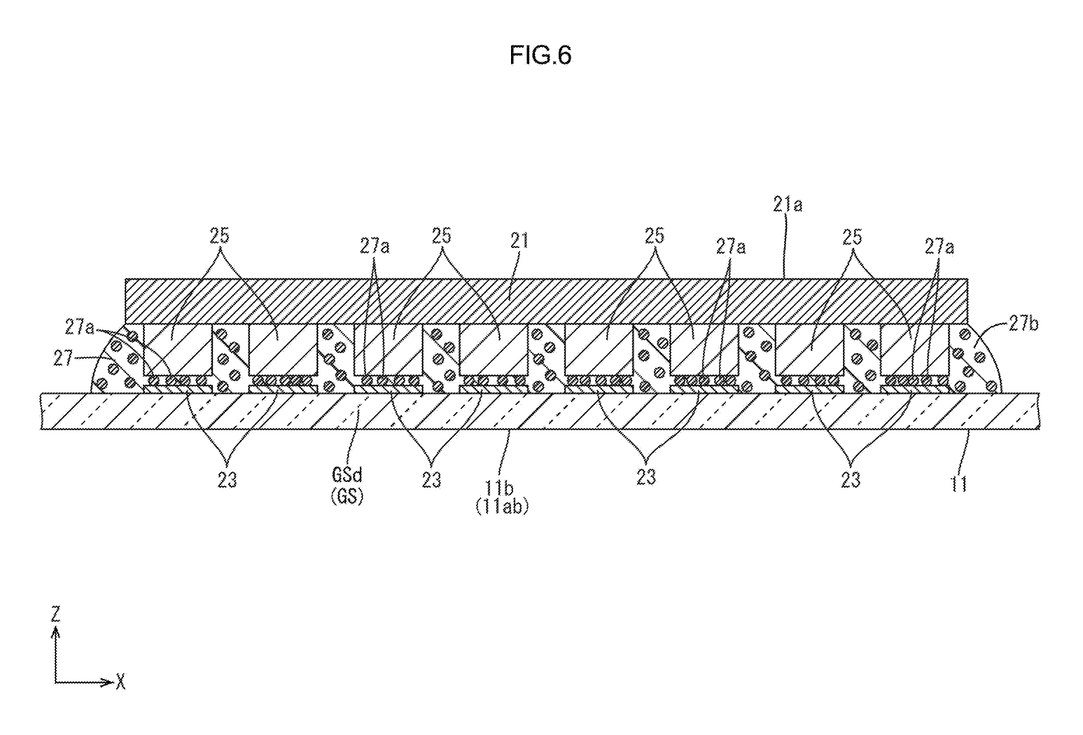

As illustrated in FIGS. 4 and 5, the panel-side input terminals 23 and the panel-side output terminals 24 are disposed in a portion of the array substrate 11b overlapping the driver 21 with a plan view, that is, a driver 21-mounting area. A group of the panel-side input terminals 23 and a group of the panel-side output terminals 24 are arranged in the Y-axis direction (in a direction that the driver 21 and the display area AA (the flexible printed circuit board 13) are arranged) with a certain distance therebetween. The panel-side input terminals 23 are arranged closer to the flexible printed circuit board 13 (on an opposite side from a display area AA side) in the driver 21-mounting area of the array substrate 11b, and the panel-side output terminals 24 are closer to the display area AA (on an opposite side from a flexible printed circuit board 13-side). As illustrated in FIG. 6, the panel-side input terminals 23 are arranged linearly and the panel-side output terminals 24 are arranged linearly in the X-axis direction, that is, in a long-side direction (a longitudinal direction) of the driver 21 with a certain distance therebetween. FIG. 6 illustrates the cross-sectional configuration of the input terminals 23 and 25, and the output terminals 24 and 26 have the similar cross-sectional configuration thereof.

As illustrated in FIG. 5, the driver-side input terminals 25 and the driver-side output terminals 26 are made of metal material having good conductivity such as gold and are metal bumps (projections) that project from a bottom surface (a surface opposite the array substrate 11b) of the driver 21. Each of the driver-side input terminals 25 and the driver-side output terminals 26 is connected to a processing circuit included in the driver 21. Input signals are input via the driver-side input terminals 25 and processed with the processing circuit and the signals are output to the driver-side output terminals 26. As illustrated in FIG. 6, similarly to the panel-side input terminals 23 are arranged linearly and the panel-side output terminals 24, the driver-side input terminals 25 are arranged linearly and the driver-side output terminals 26 are arranged linearly in the X-axis direction, that is, in a long-side direction of the driver 21, with a certain distance therebetween.

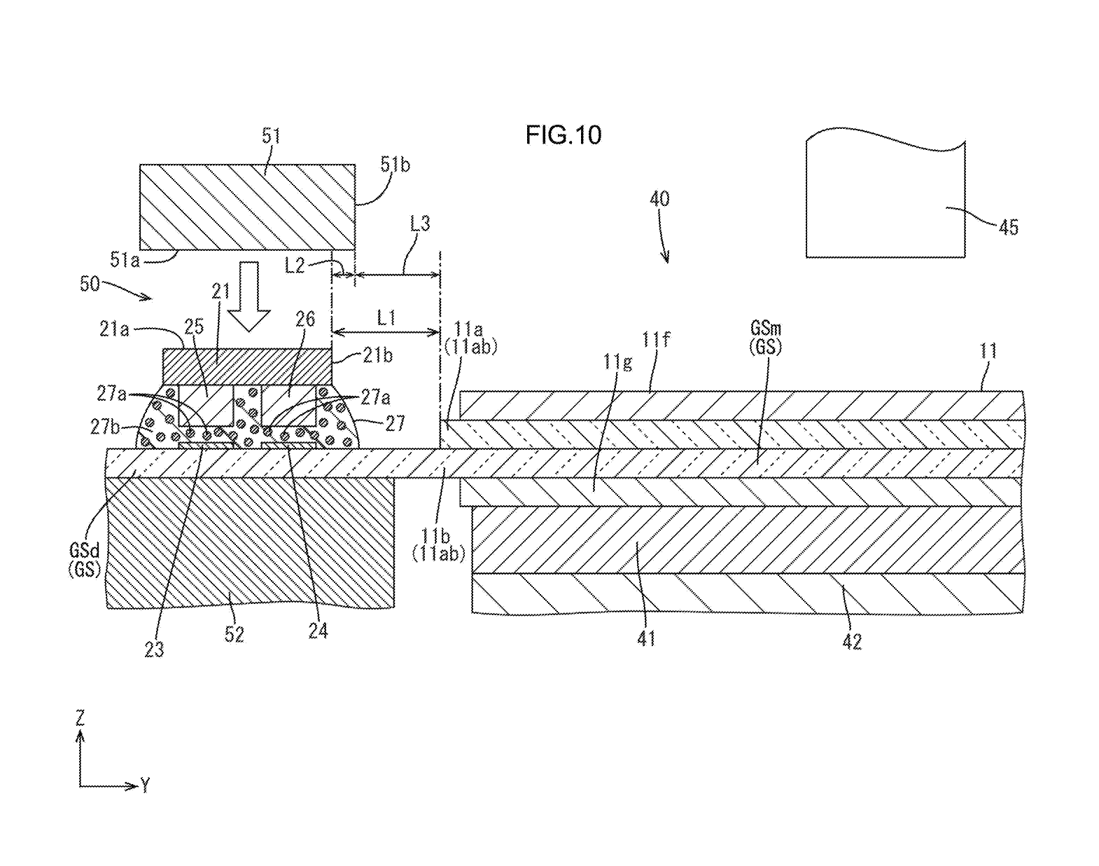

As a result of the enthusiastic studies, the applicant found the following effects. When the driver 21 is pressed on the bonded substrate 11ab, as illustrated in FIG. 10, the driver 21 and a driver-side pressing portion 51 are overlapped such that a pressing surface 51a of the driver-side pressing portion 51 is greater than the pressed surface 21a of the driver 21 by at least from 0 mm to 0.1 mm. According to such a configuration, the electrical connection between the driver-side input terminals 25 and the panel-side input terminals 23 and between the driver-side output terminals 26 and the panel-side output terminals 24 is reliable. Namely, the driver-side pressing portion 51 is positioned with respect to a direction perpendicular to a pressing direction in which the driver-side pressing portion 51 presses the driver 21 such that at least a dimension L2 (an extended amount) from an inner edge portion 21b of the driver 21 to an inner edge portion 51b of the driver-side pressing portion 51 is greater than a dimension range from 0 to 0.1 mm (L2≧0 to 0.1 mm).

The liquid crystal display device 10 has been required to be reduced in size of a frame portion and accordingly, a terminal forming portion GSt has been required to be reduced in a width dimension thereof. Therefore, as illustrated in FIG. 5, the liquid crystal panel 11 has a small-sized frame and a dimension L1 from the inner edge portion 21b of the driver 21 to a driver 21 side edge portion of the CF substrate 11a is not greater than 0.6 mm. In a configuration of very small-sized frame that is required to be reduced in a frame size such as smartphones, the dimension L1 is from 0.3 mm to 0.25 mm. With such a configuration, the driver mounting apparatus is required to have a large pressing surface of a portion that applies pressure and heat to the driver 21 (a portion corresponding to a driver-side pressing portion 51) with respect to the pressed surface 21a of the driver 21 such that the portion is surely overlapped with the driver 21. However, the driver-side pressing portion may be unintentionally in contact with the CF substrate 11a or heat from the driver-side pressing portion may be transferred to the polarizing plate 11f on the front and the properties of the polarizing plate 11f may be changed.

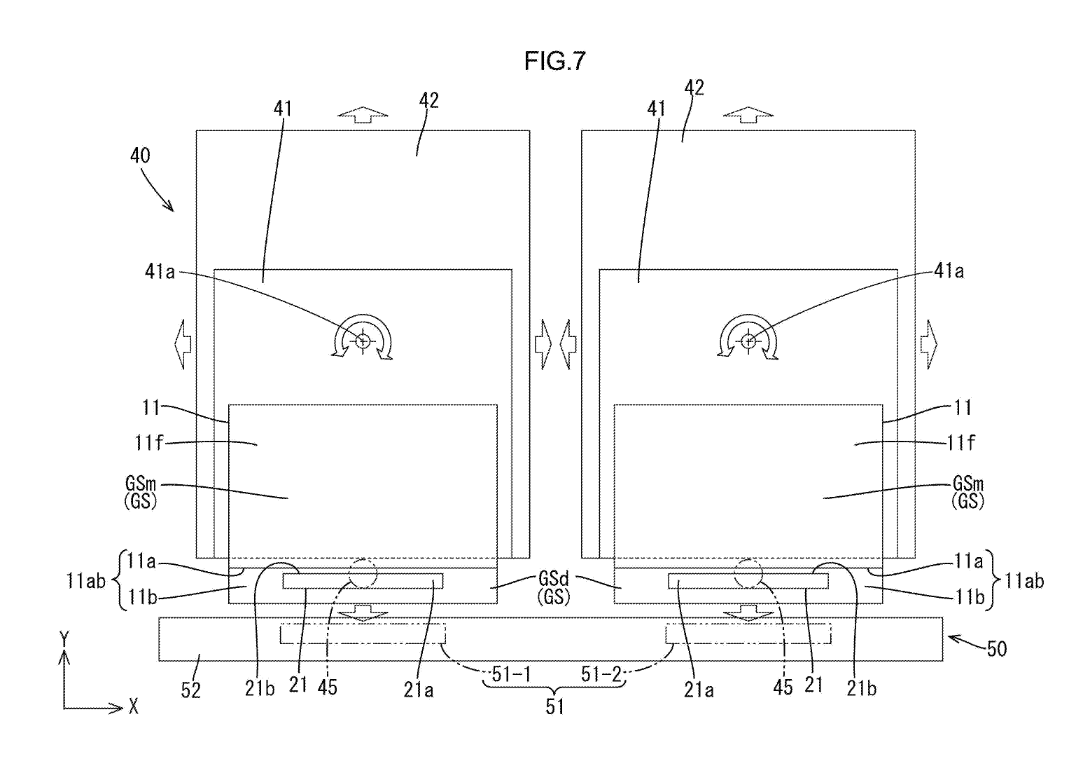

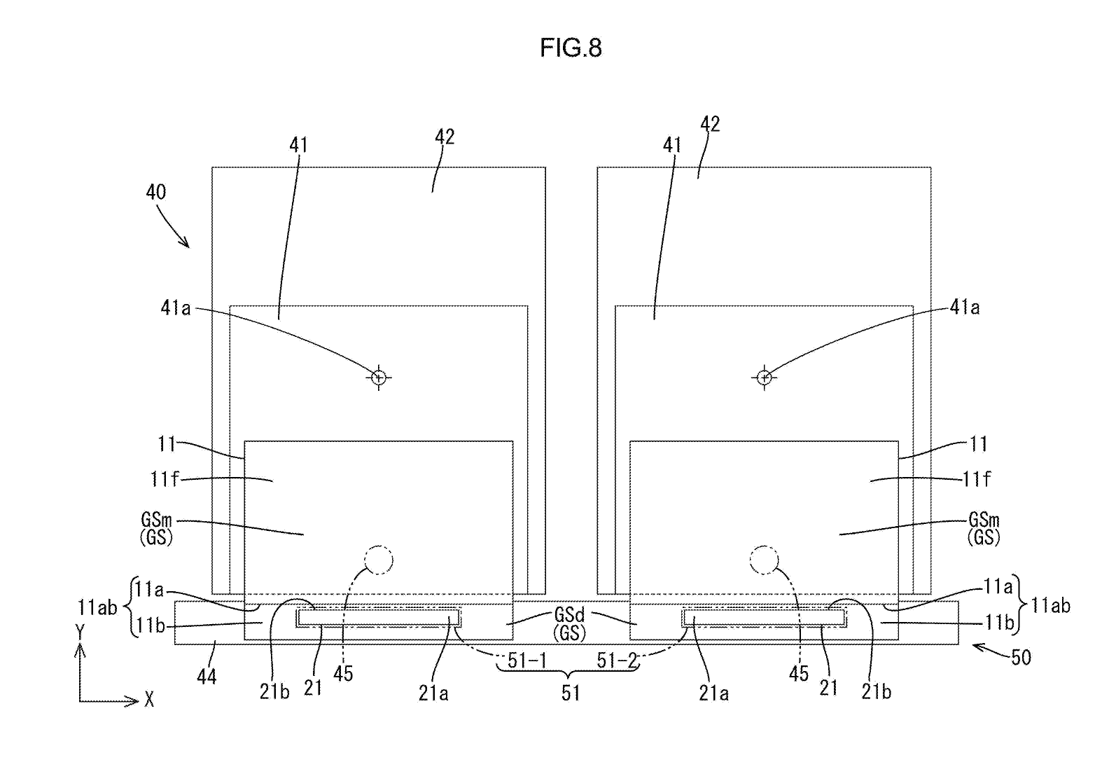

In the present embodiment, the driver mounting apparatus 40 used for mounting the driver 21 on the bonded substrate 11ab has following configuration. As illustrated in FIGS. 7 and 8, the driver mounting apparatus 40 includes a pressing device 50 for collectively pressing the drivers 21 to the panel-side input terminals 23 and the panel-side output terminals 24 of the bonded substrates 11ab, 11ab, and substrate support members 41, 41. The pressing device 50 includes the driver-side pressing portion 51 and a substrate-side pressing portion 52. The driver-side pressing portion 51 is near the driver 21 with respect to an arrangement direction in which the driver 21 and each of the panel-side input terminal 23 and the panel-side output terminal 24 are arranged. The substrate-side pressing portion 52 is near the terminals 23, 24 with respect to the arrangement direction in which the driver 21 and each of the terminals 23 and 24 are arranged. The substrate support members 41, 41 support the bonded substrates 11ab, 11ab, respectively and are independently movable such that the bonded substrate 11ab supported by each of the substrate support members 41 is positioned with respect to the corresponding driver-side pressing portion 51. In the present embodiment, the arrangement direction in which the driver 21 and each of the terminals 23, 24 are arranged matches the vertical direction (the Z-axis direction) and a plate surface direction (the X-axis direction and the Y-axis direction) of the liquid crystal panel 11 supported by the substrate support member 41 matches a horizontal direction.

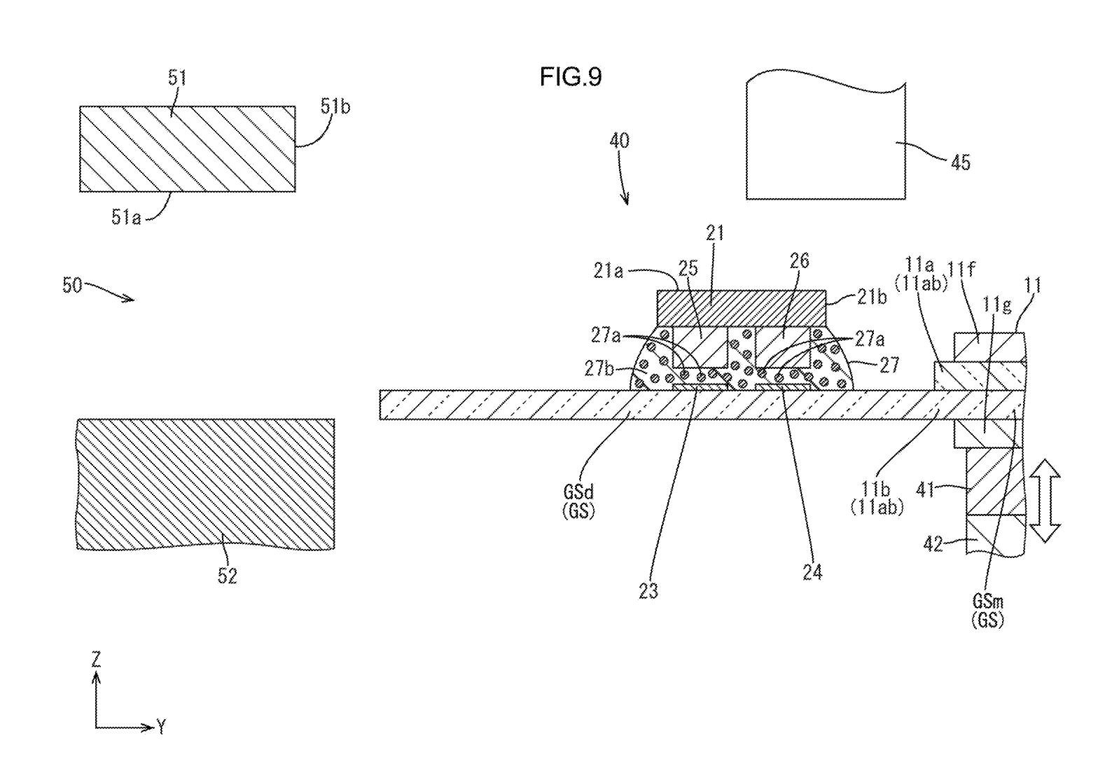

As illustrated in FIG. 9, the driver mounting apparatus 40 further includes position sensing means 45 that directly senses the driver 21 that is provisionally pressed on the panel-side input terminals 23 and the panel-side output terminals 24 before being pressed by the pressing device 50 and senses the position of at least the inner edge portion 21b of the driver 21. In the present embodiment, a camera 45 is included as the position sensing means 45. The camera 45 takes an image of the driver 21 and senses the position of at least the inner edge portion 21b of the driver 21. The camera 45 is arranged for each of the substrate support members 41 (two cameras 45 in this embodiment are).

As illustrated in FIG. 10, in the pressing device 50, the substrate-side pressing portion 52 is not movable in the Z-axis direction that is the arrangement direction in which the driver 21 and each of the panel-side input terminals 23 and the panel-side output terminals 24 (the array substrate 11b) are arranged. The driver-side pressing portion 51 is movable in the Z-axis direction and the driver-side pressing portion 51 is moved closer to the substrate-side pressing portion 52 such that the pressing portions 51, 52 hold the array substrate 11b and the driver 21 therebetween and press them. The terminals 25, 26 on the driver 21 side are electrically connected to the terminals 23, 24 on the array substrate 11b side via the conductive particles 27a contained in the anisotropic conductive film 27 by pressure force applied from the pressing device 50 to the driver 21 and the array substrate 11b. The driver-side pressing portion 51 and the substrate-side pressing portion 52 included in the pressing device 50 include heat supply means (heating means). The thermosetting resin 27b included in the anisotropic conductive film 27 that is between the driver 21 and the array substrate 11b is thermally cured by heat transferred from the heat supply means to the driver 21 and the array substrate 11b.

As illustrated in FIG. 10, the driver-side pressing portion 51 is arranged on the front with respect to the glass substrate GS to be the array substrate 11b, that is, on an opposite side from the substrate support member 41 and the substrate-side pressing portion 52. The driver-side pressing portion 51 is arranged such that the driver 21 is between the driver mount portion GSd of the glass substrate GS received by the substrate-side pressing portion 52. The driver-side pressing portion 51 is made of metal material as a whole to have good mechanical strength and thermal conductivity and includes a heater inside thereof as the heat supply means (heating means). The driver-side pressing portion 51 is supported by a lifting/lowering device (not illustrated) to be lifted and lowered in the Z-axis direction. Thus, the driver-side pressing portion 51 is relatively movable so as to be closer to or away from the driver 21 placed on the driver mount-side heat supply support member 42 and the glass substrate GS. The driver-side pressing portion 51 is not movable in the X-axis direction and in the Y-axis direction, that is, along a plate surface of the liquid crystal panel 11 and is precisely positioned in the X-axis direction and the Y-axis direction.

As illustrated in FIG. 8, the driver-side pressing portion 51 is arranged for each of the liquid crystal panels 11 and in the present embodiment, a first driver-side pressing portion 51-1 and a second driver-side pressing portion 51-2 are separately included. According to such a configuration, even if each of the liquid crystal panels 11 has variation in thickness dimension of the glass substrate GS and the driver 21, teach of the first driver-side pressing portion 51-1 and the second driver-side pressing portion 51-2 is independently lowered to apply appropriate pressing force to each liquid crystal panel 11. Each of the first driver-side pressing portion 51-1 and the second driver-side pressing portion 51-2 has a lower surface that is the pressing surface 51a that presses the driver 21. Each pressing surface 51a is larger than the pressed surface 21a of the driver 21. Namely, the pressing surface 51a is larger than the pressed surface 21a of the driver 21 having a maximum value of outer size tolerance. The pressing surface 51a is effectively larger than the pressed surface 21a of the driver 21 over an entire periphery when pressing the driver 21. According to such a configuration, the driver-side pressing portion 51 can press the entire area of the pressed surface 21a of the driver 21 with the pressing surface 51a thereof by lowering the driver-side pressing portion 51. The position relation between the driver-side pressing portion 51 and the driver 21 in pressing the driver will be described later.

As illustrated in FIG. 10, the substrate-side pressing portion 52 supports the driver mount portion GSd of the glass substrate GS of the array substrate 11b from the rear side and receives from the rear side the driver 21 and the driver mount portion GSd that are pressed by the driver-side pressing portion 51. The substrate-side pressing portion 52 is made of metal material as a whole to have good mechanical strength and thermal conductivity and includes a heater inside thereof as heat supply means (heating means). The driver mount portion GSd received by the substrate-side pressing portion 52 is a part of the glass substrate GS included in the array substrate 11b except for the substrate main portion GSm (specifically, a portion of the array substrate 11b not overlapping the CF substrate 11a). Therefore, the driver mount portion GSd has a plan-view size sufficiently greater than that of the driver 21. The substrate-side pressing portion 52 supports an entire area of the driver mount portions GSd, GSd of the bonded substrates 11ab, 11ab.

As illustrated in FIG. 7, the substrate support member 41 vacuum sucks and supports the substrate main portion GSm of the glass substrate GS of the array substrate 11b from a rear side to hold the glass substrate GS. The substrate main portion GSm supported by the substrate support member 41 is a most part of the glass substrate GS of the array substrate 11b except for the terminal forming portion GSt (specifically, a portion of the array substrate 11b overlapping the CF substrate 11a). The substrate support member 41 has a plan-view size that is substantially same or greater than that of the substrate main portion GSm of the glass substrate GS of the array substrate 11b. The substrate support member 41 is provided for each of the array substrates 11b (two substrate support members 41 in this embodiment). The substrate support member 41 includes XYθ moving means that drives the substrate support member 41 to move along a plate surface of the liquid crystal panel 11 (in the X-axis direction and the Y-axis direction) and rotatably move around a vertical axis (the Z-axis) 41a. The substrate support member 41 further includes Z moving means that drives the substrate support member 41 to move in a direction perpendicular to the plate surface of the liquid crystal panel 11 (the Z-axis direction). Specifically, the XYθ moving means and the Z moving means support the substrate support member 41 from a lower side and configure a movable stage member 42 that is fixed on the substrate support member 41. Operations of moving the substrate support member 41 will be described later.

Next, a method of manufacturing a liquid crystal panel 11 with using the above-structured driver mounting apparatus 40 will be described. The method of manufacturing the liquid crystal panel 11 includes at least a structured components forming process, a substrate bonding process, a polarizing plate attachment process, and a driver mounting process (mounting process). In the structured components forming process, metal films and insulation films are layered on an inner plate surface of each glass substrate GS of the CF substrate 11a and the array substrate 11b with the known photolithography method to form various structured components including the panel-side input terminals 23 and the panel-side output terminals 24. In the substrate bonding process, the glass substrate GS of the CF substrate 11a and the glass substrate GS of the array substrate 11b are bonded together to form the bonded substrate 11ab. In the polarizing plate attachment process, the polarizing plates 11f, 11g are attached to the respective outer plate surfaces of the bonded substrate 11ab. In the driver mounting process (mounting process), the driver 21 is mounted on the bonded substrate 11ab with using the driver mounting apparatus 40. The driver mounting process further includes at least an anisotropic conductive film applying process, a provisional pressing process, a positioning process, and a pressing process. In the anisotropic conductive film applying process, the anisotropic conductive film 27 is applied on the bonded substrate 11ab (the driver mount portion GSd). In the provisional pressing process, the driver 21 is placed on the anisotropic conductive film 27 and provisionally pressed. In the positioning process, the bonded substrate 11ab is positioned with respect to the driver-side pressing portion 51. In the pressing process, the driver 21 is pressed with the pressing device 50 (the driver-side pressing portion 51). The method of manufacturing the liquid crystal panel 11 further includes a flexible printed circuit board mounting process where the flexible printed circuit board 13 is mounted on the bonded substrate 11ab. In the driver mounting process, the driver mounting apparatus 40 is used in the positioning process and the pressing process.

Next, the positioning process and the pressing process will be described. The position of the substrate support member 41 in FIGS. 7 and 9 is referred to as a “retreat position” and the position of the substrate support member 41 in FIGS. 8 and 10 is referred to as a “forward position”. In the retreat position, the driver 21 is moved back from the driver-side pressing portion 51 and the inner edge portion 21b of the driver 21 is substantially overlapped with the camera 45. In the forward position, the driver 21 is overlapped with the driver-side pressing portion 51 as described below.

In the positioning process, two bonded substrates 11ab, 11ab on each of which the driver 21 is provisionally mounted with a provisionally pressing apparatus are placed on the two substrate support members 41, respectively. In this state, the bonded substrate 11ab is supported by the substrate support member 41 at the substrate main portion GSm from the rear side, and the polarizing plate 11g attached to the outer plate surface thereof is vacuum sucked by the substrate support member 41. Thus, the bonded substrate 11ab is firmly held by the substrate support member 41. When the bonded substrate 11ab is placed on the substrate support member 41, the substrate support member 41 may be moved back further from the retreat position in FIGS. 7 and 9, or may be shifted in the lateral direction, or may be shifted to a lower side (to be away from the camera in the Z-axis direction). Thus, the bonded substrate 11ab may be less likely to be in contact with the camera 45. The bonded substrates 11ab are to be supported by the respective substrate support members 41 until the pressing process is completed.

Next, each of the substrate support members 41 is moved to position the bonded substrate 11ab supported by each substrate support member 41 with respect to the driver-side pressing portion 51 of the pressing device 50. This process includes a position sensing process in which the driver 21 is directly detected by the camera 45 that is the position sensing means to know a position of at least the inner edge portion 21b of the driver 21 on the CF substrate 11a side. In this specification, directly detecting the driver 21 means that an image of the driver 21 itself is directly taken by a camera or the driver 21 itself is directly sensed by a sensor, and does not mean detecting a configuration other than the driver such as alignment mark on a substrate to indirectly detect the position of the driver. In the present embodiment, in the position sensing process, images of the drivers 21 on the substrate support members 41 that are in the retreat position are taken and obtained image data is processed by an image processing device included in each camera 45. Thus, information regarding the shapes and the positions of the drivers 21 are obtained. The drivers 21 have certain shape tolerances (approximately from ±40μ, to ±100μ) or mounting tolerances with respect to the array substrate 11b. The information regarding the shapes and the positions of the drivers 21 obtained in the position sensing process has accuracy not higher than that of the above tolerances.

A specific positioning method will be described below. In the retreat position in FIG 10, position information of the CF substrate 11a side inner edge portion 21b of the driver 21 is obtained by the camera 45. Based on the obtained information, the bonded substrate 11ab is positioned with respect to the driver-side pressing portion 51 (the pressing device 50) by driving the XYθ moving means of the substrate support member 41 (the movable stage member 42). Each of the driver-side pressing portion 51 (the pressing device 50) and the camera 45 is precisely positioned while the substrate support member 41 supports the liquid crystal panel 11. Each of the substrate support members 41 is moved in the arrows in FIG. 7 based on the information obtained by the camera 45 to position the liquid crystal panel 11 with respect to the driver-side pressing portion 51 (the pressing device 50) in the XYθ direction. The position of the driver mount portion GSd with respect to the Z-axis direction is detected by a position detection sensor (not illustrated) included in the driver mounting apparatus 40. The Z moving means of each substrate support member 41 (the movable stage member 42) is driven based on the position information of the driver mount portion GSd detected by the position detection sensor. Thus, the substrate support member 41 is moved in the arrow in FIG. 9 such that the lower plate surface of the array substrate 11b is on a same plane with the upper surface of the substrate-side pressing portion 52 (the pressing device 50). The positioning operations are executed simultaneously for the liquid crystal panels 11 and therefore, the positioning operations of the liquid crystal panels 11 are executed in a same tact. The substrate support members 41 are moved from the retreat position to the forward position with the drivers 21 being positioned in the correct positions on the bonded substrates 11ab with respect to the XYZθ direction. Then, each driver 21 is positioned in a certain position with respect to the driver-side pressing portion 51.

As illustrated in FIGS. 5 and 6, the CF substrate 11a and the polarizing plate 11f of the bonded substrate 11ab are close to the pressed surface 21a of the driver 21 (L1≦0.6 mm, L1=0.3 mm or 0.25 mm) and other components are not close to the pressed surface 21a. In the forward position of the substrate support member 41 in FIG. 10, the pressing surface 51a of the driver-side pressing portion 51 is larger than the pressed surface 21a of the driver 21 such that the extended amount L2 of the pressing surface 51a from the CF substrate 11a side inner edge portion 21b of the driver 21 is within a range from 0 mm to 0.1 mm. An extended amount of the pressing surface 51a from other edge portions of the driver 21 is at least 0.1 mm or more such that the shape tolerances of the driver 21, the mounting tolerances of the driver 21 and the array substrate 11b, and the position errors of the driver-side pressing portion 51 and the driver 21 are cancelled. The inner edge portion 21b of the driver 21 is positioned with respect to the inner edge portion 51b of the driver-side pressing portion 51. Accordingly, the drivers 21 are positioned with respect to the respective driver-side pressing portions 51 such that the pressing surface 51a of each driver-side pressing portion 51 is overlapped with the pressed surface 21a of each driver 21 over a substantially entire area.

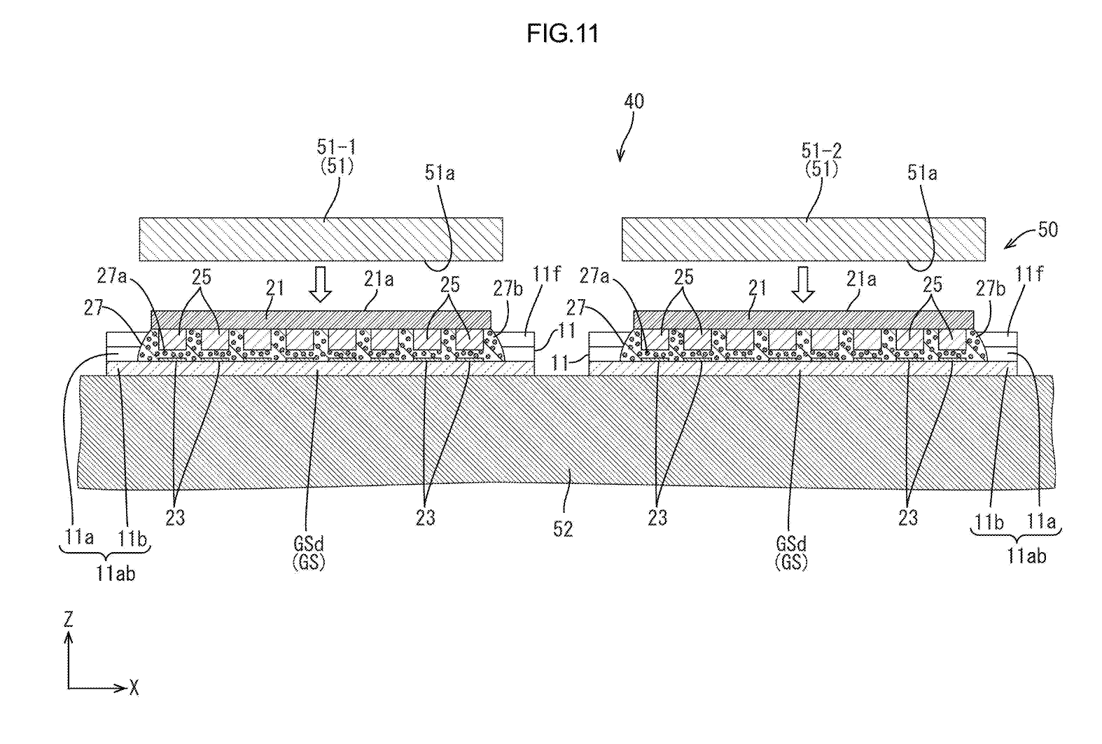

Next, in the pressing process, the driver-side pressing portion 51 is lowered in the Z-axis direction and the driver-side pressing portion 51 is moved closer to the substrate-side pressing portion 52. The driver-side pressing portion 51 is in contact with the driver 21 and the substrate-side pressing portion 52 is in contact with the driver mount portion GSd. The driver mount portion GSd is supplied with heat from the driver-side pressing portion 51 and the substrate-side pressing portion 52. The heat supplied to the driver mount portion GSd and the driver 21 from the contact of the pressing portions 51, 52 is transferred to the thermosetting resin 27b contained in the anisotropic conductive film 27 and promotes thermosetting of the thermosetting resin 27b. If the driver-side pressing portion 51 is further lowered from the contact state, pressure force is applied to the driver 21, the driver mount portion GSd, and the anisotropic conductive film 27 sandwiched by the driver mount-side heat supply support member 42 and the driver-side pressing portion 51. The driver-side pressing portion 51 is stopped if the driver-side pressing portion 51 reaches a certain height position and the application of pressure force and supply of heat is still continued for a certain period. Accordingly, as illustrated in FIGS. 5 and 6, the terminals 25, 26 on the driver 21 side are electrically connected to the terminals 23, 24 on the array substrate 11b side via the conductive particles 27a contained in the anisotropic conductive film 27, and the thermosetting resin 27b included in the anisotropic conductive film 27 is thermally cured, and the driver 21 is pressed on the driver mount portion GSd. In the pressing process, the driver-side pressing portion 51 and the substrate-side pressing portion 52 supply heat such that temperature of a connection surface of the terminals 25, 26 on the driver 21 side and the terminals 23, 24 on the array substrate 11b side is from 80° C. to 150° C. and apply a load of 100N to 450N to the driver mount portion GSd. After completion of the pressing described above, the supply of heat from the driver-side pressing portion 51 and the substrate-side pressing portion 52 is stopped and the driver-side pressing portion 51 is lifted upward in the Z-axis direction to be away from the driver 21. As illustrated in FIG. 11, the operations of the pressing process are executed simultaneously for the bonded substrates 11ab and the driving of the pressing device 50 is executed collectively for the bonded substrates 11ab.

As described before, the driver mounting apparatus 40 of the present embodiment includes the pressing device 50 and the substrate support members 41, 41. The pressing device 50 collectively presses the drivers 21 on the respective bonded substrates 11ab, 11ab such that each driver 21 is mounted on the terminals 23, 24. The bonded substrate 11ab is obtained by bonding the CF substrate 11a and array substrate 11b having the panel-side input terminals 23 and the panel-side output terminals 24 such that the terminals 23, 24 are uncovered. The pressing device 50 includes the driver-side pressing portion 51 and the substrate-side pressing portion 52. The driver-side pressing portion 51 is arranged near the driver 21 in the arrangement direction in which the driver 21 and the terminals 23, 24 are arranged, and the substrate-side pressing portion 52 is arranged near the terminals 23, 24 in the arrangement direction. The substrate support members 41, 41 support the bonded substrates 11ab, 11ab, respectively, and independently move to position the respective liquid crystal panel 11 thereon with respect to the corresponding driver-side pressing portion 51.

In the driver mounting apparatus 40 of the present embodiment, the substrate support members 41, 41 are movable independently from each other. Therefore, in collectively pressing the drivers 21 on the respective bonded substrates 11ab, 11ab, the driver-side pressing portion 51 is less likely to be in contact with the CF substrate 11a or the polarizing plate 11f, and mounting failure of the drivers 21 is less likely to occur. Specifically, in the driver mounting apparatus 40 of the present embodiment, the position relation between the driver-side pressing portion 51 and the driver 21 is adjusted for each bonded substrate 11ab when collectively pressing the drivers 21 on the respective bonded substrates 11ab, 11ab. Therefore, position errors of each bonded substrate 11ab (each driver 21) are cancelled. According to such a configuration, the size of the pressing surface 51a of the driver-side pressing portion 51 is not necessary to be much larger than the size of the pressed surface 21a of the driver 21, or the extended amount L2 of the pressing surface 51a of the driver-side pressing portion 51 from the pressed surface 21a of the driver 21 on the CF substrate 11a side is not necessary to be much greater than L1. Thus, the driver-side pressing portion 51 is pressed to the driver 21 with being surely overlapped with the driver 21 and keeping the L3 (L1-L2).

In the present embodiment, a position of the bonded substrate 11ab around an axis (the Z-axis) 41a that is vertical to the plate surface of the bonded substrate 11ab is adjusted, since the substrate support member 41 includes the XYθ moving means. It is difficult to adjust the position around the axis 41a if one substrate support member 41 supports multiple bonded substrates 11ab. Further, in the present embodiment, the driver-side pressing portion 51 is pressed on the driver with being surely overlapped with the driver and not in contact with other components. Especially in the present embodiment, the driver 21 extends in the X-axis direction. Therefore, even if the positioning error (angular displacement) around the axis (the Z-axis) 41a that is vertical to the plate surface is quite small, the positioning error greatly influences the extended amount L2 at the two end portions of the elongated driver 21. Therefore, the adjustment around the axis 41a is effective in the present embodiment.

In the present embodiment, the substrate support member 41 further includes the Z moving means. Therefore, each of the bonded substrates 11ab is positioned with respect to the pressing device 50 in the direction vertical to the plate surface of the liquid crystal panel 11 (the Z-axis direction) even if the bonded substrates 11ab and the drivers 21 have variation in thickness dimensions thereof. Therefore, a force is not applied to the driver 21 to be rotated when the driver 21 is pressed. The driver 21 is pressed with surely overlapped with the driver-side pressing portion 51, even if the extended amount L2 of the driver-side pressing portion 51 from the driver 21 is small.

In the present embodiment, the camera 45 that is the position sensing means is further included. The bonded substrate 11ab is positioned with respect to the driver-side pressing portion 51 by the substrate support member 41 based on the position information of the driver 21 that is obtained by the position sensing means. Even if the drivers 21 have great size tolerances or the mount positions of the drivers with respect to the bonded substrates 11ab are greatly varied, the position of each driver 21 is directly sensed by the camera 45. Therefore, accuracy of positioning the driver 21 and the driver-side pressing portion 51 is improved, compared to means of positioning the driver based on detected position of an alignment mark on each substrate. In the present embodiment, the camera 45 that is included as the position sensing means directly takes an image of the driver 21 and the image data is processed. Thus, the position of each driver 21 is effectively obtained.

According to the method of mounting a driver of the present embodiment, the bonded substrate 11ab is obtained by bonding the CF substrate 11a and array substrate 11b having the panel-side input terminals 23 and the panel-side output terminals 24 such that the terminals 23, 24 are uncovered. The driver 21 is mounted on the terminals 23, 24. The method includes a provisional pressing process, a positioning process, and a pressing process. In the provisional pressing process, the driver 21 is provisionally pressed on the terminals 23, 24. In the positioning process, the bonded substrates 11ab, 11ab where the respective drivers 21 are provisionally pressed are supported by the substrate support members 41, 41, respectively, each of which is independently movable. Each substrate support member 41 is moved with respect to the driver-side pressing portion 51 of the pressing device 50 that is arranged on the driver 21 side in the arrangement direction where the driver 21 and the terminals 23, 24 are arranged. Thus, each of the bonded substrates 11ab supported by the respective substrate support members 41 is positioned. In the pressing process, the driver-side pressing portion 51 and the substrate-side pressing portion 52 are relatively closer to each other such that the drivers 21 are collectively pressed on the terminals 23, 24 of the bonded substrates 11ab, 11ab. The pressing device 50 includes the driver-side pressing portion 51 and the substrate-side pressing portion 52. The substrate-side pressing portion 52 is arranged near the terminals 23, 24 via the array substrate 11b in the arrangement direction in which the driver 21 and the terminals 23, 24 are arranged.

The method of mounting a driver according to the present embodiment includes the positioning process in which each of the bonded substrates 11ab, 11ab is positioned with respect to the driver-side pressing portion 51. Therefore, in collectively pressing the drivers 21 on the respective bonded substrates 11ab, 11ab, the driver-side pressing portion 51 is less likely to be in contact with other components, and mounting failure of the drivers 21 is less likely to occur. Specifically, in the driver mounting apparatus 40 of the present embodiment, the position relation between the driver-side pressing portion 51 and the driver 21 is adjusted for each bonded substrate 11ab when collectively pressing the drivers 21 on the respective bonded substrates 11ab, 11ab. Therefore, position errors of each bonded substrate 11ab (each driver 21) are cancelled. Therefore, the size of the pressing surface 51a of the driver-side pressing portion 51 is not necessary to be much larger than the size of the pressed surface 21a of the driver 21, or the extended amount L2 of the pressing surface 51a of the driver-side pressing portion 51 from the pressed surface 21a of the driver 21 on the CF substrate 11a side is not necessary to be much greater. Thus, the driver-side pressing portion 51 is pressed to the driver 21 with being surely overlapped with the driver 21.

The positioning process of the present embodiment includes the position sensing process. Therefore, the liquid crystal panel 11 is positioned with respect to the pressing device 50 by moving the substrate support member 41 based on the position information of the driver 21 that is obtained by the camera 45. Even if the drivers 21 have great size tolerances or the mount positions of the drivers 21 with respect to the liquid crystal panel 11 are greatly varied, accuracy of positioning of the driver 21 and the driver-side pressing portion 51 is improved, compared to means of positioning the driver based on detected position of an alignment mark on each substrate.

### Second Embodiment

A second embodiment of the present invention will be described with reference to FIGS. 12 to 14. In the second embodiment, a flexible printed circuit board mounting apparatus 140 and a method of mounting a flexible printed circuit board will be described. The flexible printed circuit board 13 is mounted on the external connection terminals 22 (corresponding to the terminal in claim) by the flexible printed circuit board mounting apparatus 140. The flexible printed circuit board mounting apparatus 140 may be called as a film on glass (FOG) apparatus. Configurations, operations, and effects similar to those in the first embodiment will not be described.

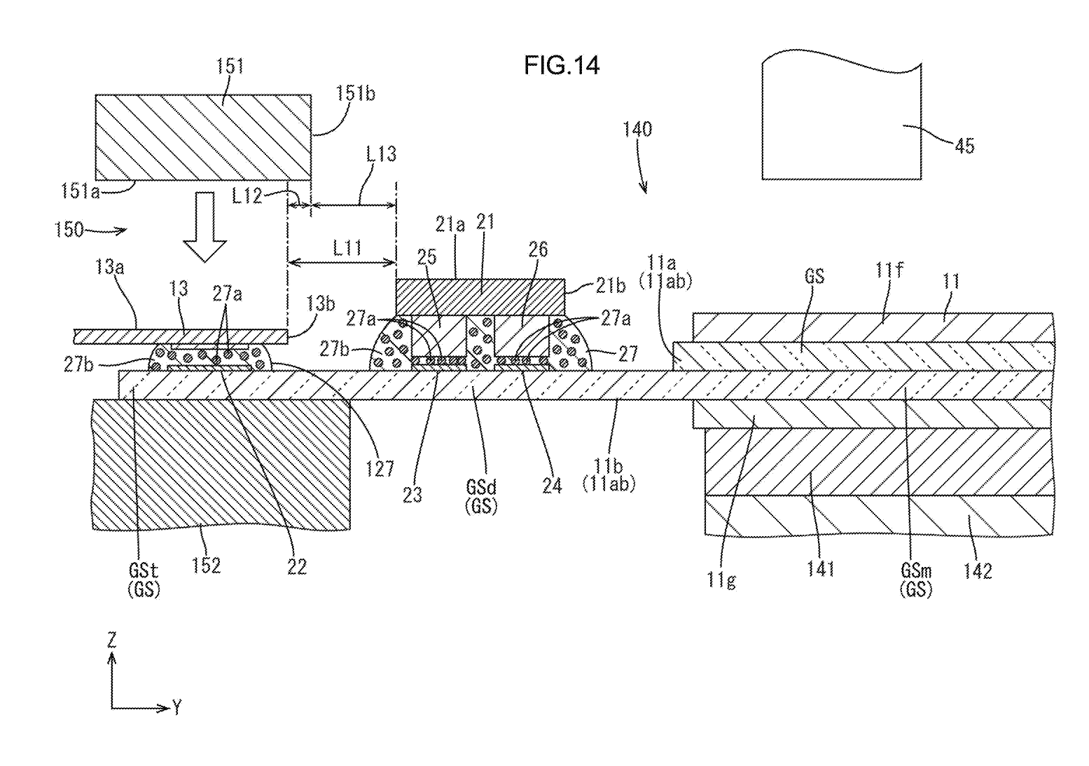

As illustrated in FIG. 14, the flexible printed circuit board mounting apparatus 140 of the present embodiment includes a pressing device 150 for collectively pressing the drivers 21 to the external connection terminals 22 of the bonded substrates 11ab, 11ab (two in this embodiment), and substrate support members 141, 141. The pressing device 150 includes a FPC-side pressing portion 151 and a substrate-side pressing portion 152. The FPC-side pressing portion 151 is near the flexible printed circuit board 13 with respect to an arrangement direction in which the flexible printed circuit board 13 and the external connection terminal 22 are arranged. The substrate-side pressing portion 152 is near the external connection terminals 22 with respect to the arrangement direction in which the flexible printed circuit board 13 and the external connection terminals 22 are arranged. The array substrate 11b is between the substrate-side pressing portion 152 and the external connection terminals 22. The substrate support members 141, 141 support the bonded substrates 11ab, 11ab, respectively and are independently movable such that the bonded substrate 11ab supported by each of the substrate support members 141 is positioned with respect to the driver-side pressing portion 51. In the configuration of the pressing device 150, the FPC-side pressing portion 151 is extended from an inner edge portion 13b of the flexible printed circuit board 13 on the CF substrate 11a side, and the FPC-side pressing portion 151 is not extended from an edge portion opposite from the inner edge portion 13b. Other configuration of the pressing device 150 is similar to that of the pressing device 50 and will not be described. The substrate support member 141 and a movable stage member 142 have configurations similar to those of the substrate support member 41 and the movable stage member 42 and will not be described.

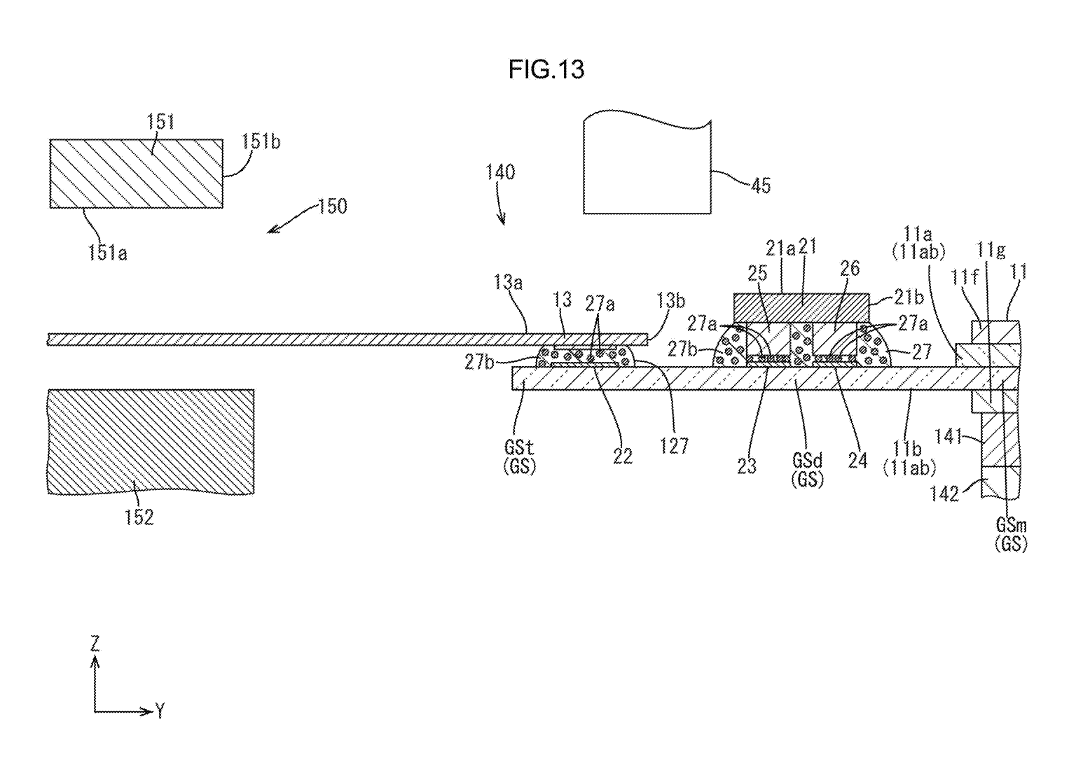

As illustrated in FIG. 13, the flexible printed circuit board mounting apparatus 140 further includes the position sensing means 45 that directly detects the flexible printed circuit board 13 that is provisionally pressed on the external connection terminals 22 before being mounted by the pressing device 150 and senses the position of at least the CF substrate 11a side edge portion of the flexible printed circuit board 13. In the present embodiment, the camera 45 is included as the position sensing means 45. The camera 45 directly takes an image of the flexible printed circuit board 13 and senses the position of at least the CF substrate 11a side edge portion of the flexible printed circuit board 13. The camera 45 is arranged for each of the substrate support members 141 (two cameras 45 in this embodiment).

Next, a method of manufacturing the liquid crystal panel 11 using the above-structured flexible printed circuit board mounting apparatus 140 will be described. In the present embodiment, the method of manufacturing the liquid crystal panel 11 further includes a flexible printed circuit board mounting process after the pressing process of the first embodiment, and the flexible printed circuit board 13 is mounted on the bonded substrate 11ab in the flexible printed circuit board mounting process. The flexible printed circuit board mounting process includes at least an anisotropic conductive film applying process, a provisional pressing process, a positioning process, and a pressing process. In the anisotropic conductive film applying process, the anisotropic conductive film 127 is applied on the bonded substrate 11ab to overlap the external connection terminals 22. In the provisional pressing process, the flexible printed circuit board 13 is placed on the anisotropic conductive film 127 and provisionally pressed. In the positioning process, the bonded substrate 11ab is positioned with respect to the FPC-side pressing portion 151. In the pressing process, the flexible printed circuit board 13 is pressed with the pressing device 150 (the FPC-side pressing portion 151). Mounting components are different in the positioning process and the pressing process of the present embodiment from those in the first embodiment. However, other operations are similar to those of the first embodiment and will not be described.

The liquid crystal display device 10 has been required to be reduced in size of a frame portion and accordingly, the terminal forming portion GSt has been required to be reduced in a width dimension thereof. Therefore, the liquid crystal panel 11 has a small-sized frame having a small dimension L11 that is from the inner edge portion 13b of the flexible printed circuit board 13 to an outer edge portion of the driver 21 similarly to the dimension L1 of the first embodiment. With such a configuration, the flexible printed circuit board mounting apparatus is required to have a large pressing surface of a portion that applies pressure and heat to the flexible printed circuit board 13 (a portion corresponding to the FPC-side pressing portion 151) with respect to the pressed surface 21a of the flexible printed circuit board 13 such that the portion is surely overlapped with the flexible printed circuit board 13. However, the FPC-side pressing portion may be unintentionally in contact with the driver 21 and heat from the FPC-side pressing portion may change the properties of the anisotropic conductive film 27 between the driver 21 and each of the panel-side input terminals 23 and the panel-side output terminals 24.

In the flexible printed circuit board mounting apparatus 140 of the present embodiment, the substrate support members 141, 141 are movable independently from each other. The method of mounting the flexible printed circuit board 13 according to the present embodiment includes the positioning process in which each of the bonded substrates 11ab, 11ab is positioned with respect to the driver-side pressing portion 51. Therefore, in collectively pressing the flexible printed circuit boards 13 on the respective bonded substrates 11ab, 11ab, the FPC-side pressing portion 151 is less likely to be in contact with the driver 21, and mounting failure of the flexible printed circuit boards 13 is less likely to occur. Specifically, in the flexible printed circuit board mounting apparatus 140 of the present embodiment, the position relation between the FPC-side pressing portion 151 and the flexible printed circuit board 13 is adjusted for each bonded substrate 11ab when collectively pressing the flexible printed circuit boards 13 on the respective bonded substrates 11ab, 11ab. Therefore, position errors of each bonded substrate 11ab (each flexible printed circuit board 13) are cancelled. Therefore, the size of the pressing surface 51a of the FPC-side pressing portion 151 is not necessary to be much larger than the size of the pressed surface 21a of the flexible printed circuit board 13, or an extended amount L12 of the pressing surface 51a of the FPC-side pressing portion 51 from the pressed surface 21a of the flexible printed circuit board 13 on the driver 21 side is not necessary to be much greater than L11. Thus, the FPC-side pressing portion 151 is pressed on the flexible printed circuit board 13 with being surely overlapped with the flexible printed circuit board 13 and keeping L13 (L11-L12).

### Other Embodiments

The present invention is not limited to the embodiments, which have been described using the foregoing descriptions and the drawings. For example, embodiments described below are also included in the technical scope of the present invention.

(1) In each of the above embodiments, the two substrate support members are included. However, the number of the substrate support members is not necessarily two but may be three or more.

(2) In each of the above embodiments, the component-side pressing portion includes multiple portions corresponding to multiple bonded substrates. However, the component-side pressing portion does not necessarily have such a configuration. One component-side pressing portion may be included for multiple bonded substrates (for example, one component-side pressing portion is included for two bonded substrates), or multiple component-side pressing portions may be included for multiple bonded substrates (for example, two component-side pressing portions are included for four bonded substrates).

(3) In each of the above embodiments, as the mounting substrate manufacturing apparatus and the method of manufacturing a mounting substrate, an apparatus and a method of pressing a driver and a flexible printed circuit board are described. However, operations of the pressing are not limited thereto. For example, the technical matters of the present invention may be applied to an apparatus and a method of provisionally pressing the driver and the flexible printed circuit board.

(4) In each of the above embodiments, the camera that is configured to take an image of an object on a X-Y plane is used as the position detection means. However, the position detection means is not limited thereto. The position detection means may be means of irradiating the object with laser and detecting unevenness on the X-Y plane (a thickness of the mount component such as a driver).

(5) In each of the above embodiments, the position detection sensor detects a height position of an outer side plate surface of a glass substrate (a printed circuit board) and the Z moving means is controlled based on the detected results. However, the position detection means is not limited thereto.

(6) In each of the above embodiments, the substrate-side pressing portion is fixed within the apparatus. However, it is not limited thereto. For example, the substrate-side pressing portion may be movable in the Z-axis direction similarly to the component-side pressing portion. The substrate support member may be extended to a driver mount portion of the glass substrate such that the substrate-side pressing portion and the substrate support member may be integrally provided with each other and the substrate-side pressing portion may be moved in conjunction with the substrate support member.

(7) In each of the above embodiments, a buffer may be included between the mounting component and the component-side pressing portion.

(8) In the above embodiments, the driver and the flexible circuit printed board are used as the mounting component. However, it is not limited thereto. Other than the above embodiments, the technical matters of the present invention may be applied to a flexible printed circuit board mounting apparatus for mounting a flexible printed circuit board having a driver on the printed circuit board or a mounting method thereof.

(9) In each of the above embodiments, an elongated driver is used as the mounting component. For example, a driver having a square plan-view shape may be used as the component.

(10) In each of the above embodiments, one mounting component (a driver or a flexible printed circuit board) is mounted on one liquid crystal panel. However, multiple mounting components may be mounted on one liquid crystal panel.

(11) Each of the above embodiments describes a manufacturing apparatus for mounting the driver and the flexible printed circuit board on the array substrate included in a transmissive liquid crystal display device including a backlight device as an external light source and a manufacturing method with using the apparatus. The present invention may be applied to a manufacturing apparatus for mounting the driver and the flexible printed circuit board on the array substrate included in a reflective liquid crystal display device using external light and a manufacturing method with using the apparatus.

(12) In each of the embodiments, the TFTs are used as switching components of the liquid crystal display device. However, a manufacturing apparatus for mounting the driver and the flexible printed circuit board on the array substrate included in liquid crystal display devices that include switching components other than TFTs (e.g., thin film diodes (TFDs)) and a manufacturing method with using the apparatus may be included in the scope of the present invention. Furthermore, a manufacturing apparatus for mounting the driver and the flexible printed circuit board on the array substrate included in black-and-white liquid crystal display devices, other than color liquid crystal display device, and a manufacturing method with using the apparatus are also included in the scope of the present invention.

(13) The manufacturing apparatus for mounting the driver and the flexible printed circuit board on the bonded substrate (the array substrate) included in liquid crystal display devices including the liquid crystal panels as the display panels and a manufacturing method with using the apparatus are described as the embodiments. However, a manufacturing apparatus for mounting the driver and the flexible printed circuit board on the bonded substrate included in display devices that include other types of display panels (e.g., plasma display panels (PDPs) and organic EL panels) and a manufacturing method with using the apparatus are also included in the scope of the present invention.

### EXPLANATION OF SYMBOLS

11: liquid crystal panel (substrate), 11ab: bonded substrate, 11a: CF substrate (first substrate), 11b: array substrate (second substrate), 13: flexible printed circuit board (mounting component), 21: driver (mounting component), 21b: inner edge portion, 22: external connection terminal (terminal), 23: panel0side input terminal (terminal), 24: panel-side output terminal (terminal), 40: driver mounting apparatus (manufacturing apparatus), 41, 141: substrate support member, 42, 142: movable stage member (XYθ moving means, Z moving means), 45: camera (position sensing means), 50, 150: pressing device (pressing device), 51, 151: driver-side pressing portion (component-side pressing portion), 52: substrate-side pressing portion, 140: flexible printed circuit mounting apparatus (manufacturing apparatus), 151: FPC-side pressing portion (mounting component-side pressing portion)

1. A mounting substrate manufacturing apparatus comprising:
a pressing device that collectively presses mounting components that are to be mounted on terminals of bonded substrates each of which is obtained by bonding a first substrate and a second substrate having terminals with the terminals being uncovered, the pressing device including
a mounting component-side pressing portion that is arranged close to the mounting components with respect to an arrangement direction in which the mounting components and the terminals are arranged, and
a substrate-side pressing portion that is arranged close to the terminals with respect to the arrangement direction in which the mounting components and the terminals are arranged, the second substrate being between the substrate-side pressing portion and the terminals; and
substrate support members supporting the bonded substrates, respectively, and being movable independently from each other to position each of the bonded substrates supported on the substrate support members with respect to the mounting component-side pressing portion.

2. The mounting substrate manufacturing apparatus according to claim 1, wherein each of the substrate support members includes XYθ moving means for moving the bonded substrate in a plate surface direction thereof and around an axis that is vertical to the plate surface direction.

3. The mounting substrate manufacturing apparatus according to claim 2, wherein each of the substrate support members includes Z moving means for moving the bonded substrate in a direction vertical to the plate surface direction of the bonded substrate.

4. The mounting substrate manufacturing apparatus according to claim 1, further comprising:
position sensing means directly sensing the mounting component that is provisionally pressed on the terminals before being pressed by the pressing device and detecting a position of at least a first substrate side edge portion of the mounting component, wherein
each of the bonded substrates is positioned with respect to the mounting component-side pressing portion by the substrate support member based on information regarding the position of the mounting component sensed by the position sensing means.

5. The mounting substrate manufacturing apparatus according to claim 4, wherein the position sensing means is a camera that directly takes an image of the mounting component and senses the position of at least the first substrate-side edge portion of the mounting component.

6. A method of manufacturing a mounting substrate comprising:
a provisional pressing process in which mounting components are provisionally pressed on terminals on bonded substrates each of which is obtained by bonding a first substrate and a second substrate having the terminals with uncovered;
a positioning process in which the bonded substrates having the mounting components provisionally pressed are supported on substrate support members each of which is movable independently, and each of the substrate support members is moved and positioned with respect to a mounting component-side pressing portion that is included in a pressing device and arranged close to the mounting components with respect to an arrangement direction in which the mounting components and the terminals are arranged; and
a pressing process in which the mounting component-side pressing portion and a substrate-side pressing portion of the pressing device are relatively closer to each other, the substrate-side pressing portion being arranged close to the terminals having the second substrate therebetween with respect to the arrangement direction in which the mounting components and the terminals are arranged, and the mounting components are collectively pressed on the terminals on the respective bonded substrates.

7. The method of manufacturing a mounting substrate according to claim 6, wherein
in the positioning process, the mounting components that are provisionally pressed are directly sensed by position sensing means to detect a position of at least a first substrate-side edge portion of each mounting component.
